(19) United States
(12) Patent Application Publication
(10) Pub. No.: US 2023/0292537 A1
(43) Pub. Date: Sep. 14, 2023

(54) LIGHT EMITTING DEVICE THAT EMITS GREEN LIGHT, AND LIGHT EMITTING SUBSTRATE AND LIGHT EMITTING APPARATUS

(71) Applicant: BOE TECHNOLOGY GROUP CO., LTD., Beijing (CN)

(72) Inventors: Kun MA, Beijing (CN); Rongrong GAO, Beijing (CN); Dan WANG, Beijing (CN)

(73) Assignee: BOE TECHNOLOGY GROUP CO., LTD., Beijing (CN)

(21) Appl. No.: 18/014,853

(22) PCT Filed: Nov. 22, 2021
(86) PCT No.: PCT/CN2021/132200

§ 371 Date: Jan. 6, 2023

(30) Foreign Application Priority Data
Mar. 29, 2021 (CN) 202110336552.X

(51) Int. Cl. H10K 50/11; H10K 59/95; H10K 85/60; H10K 50/16

(52) U.S. Cl. CPC H10K 50/11; H10K 59/95; H10K 85/6572; H10K 50/16; H10K 2101/25

(57) ABSTRACT

A light-emitting device that emits green light includes a first electrode and a second electrode that are arranged in sequence, and a light-emitting layer disposed between the first electrode and the second electrode, the light-emitting layer includes a first host material and a second host material; the first host material and the second host material form an exciplex, a difference between a lowest unoccupied molecular orbital (LUMO) energy level of the first host material and a LUMO energy level of the second host material is greater than or equal to 0.5 eV, under a same test condition, a difference between an order of magnitude of a hole mobility of the first host material and an order of magnitude of an electron mobility of the second host material is greater than or equal to 1.

### CROSS-REFERENCE TO RELATED APPLICATIONS

This application is a national phase entry under 35 USC 371 of International Patent Application No. PCT/CN2021/132200, filed on Nov. 22, 2021, which claims priority to Chinese Patent Application No. 202110336552,X, filed on Mar. 29, 2021, which are incorporated herein by reference in their entirety.

### TECHNICAL FIELD

The present disclosure relates to the fields of lighting and display technologies, and in particular, to a light-emitting device that emits green light, a light-emitting substrate and a light-emitting apparatus.

### BACKGROUND

Organic light-emitting diodes (OLEDs) have characteristics of self-luminescence, wide viewing angle, quick response, high luminous efficiency, low operating voltage, small substrate thickness, being capable of being used for manufacturing a large-sized and bendable substrate, simple manufacturing process and the like, and is known as a next-generation “star” in the display technology.

### SUMMARY

In an aspect, a light-emitting device that emits green light is provided. The light-emitting device that emits the green light includes a first electrode and a second electrode that are arranged in sequence, and a light-emitting layer disposed between the first electrode and the second electrode. The light-emitting layer includes a first host material and a second host material, and the first host material and the second host material form an exciplex. A difference between a lowest unoccupied molecular orbital (LUMO) energy level of the first host material and a LUMO energy level of the second host material is greater than or equal to 0.5 eV; under a same test condition, a difference between an order of magnitude of a hole mobility of the first host material and an order of magnitude of an electron mobility of the second host material is greater than or equal to 1.

In some embodiments, under a test condition where an electric field intensity is 5000 V^{1/2}/m^{1/2}, the hole mobility of the first host material is in a range from 1×10⁻⁸ cm²V⁻¹s⁻¹ to 1×10⁻⁶ cm²V⁻¹s⁻¹ inclusive, and the electron mobility of the second host material is in a range from 1×10⁻⁹ cm²V⁻¹s⁻¹ to 1×10⁻⁶ cm²V⁻¹s⁻¹, inclusive.

In some embodiments, the LUMO energy level of the first host material is in a range from −2.4 eV to −2.0 eV, inclusive; the LUMO energy level of the second host material is in a range from −3.0 eV to −2.7 eV, inclusive.

In some embodiments, a full width at half maximum of an emission spectrum of the exciplex is greater than or equal to 90 nm.

In some embodiments, the full width at half maximum of the emission spectrum of the exciplex is in a range from 100 nm to 110 nm, inclusive.

In some embodiments, the first host material is selected from structures each having two carbazoles.

In some embodiments, the first host material is selected from structures represented by following general formula (I) and general formula (II):

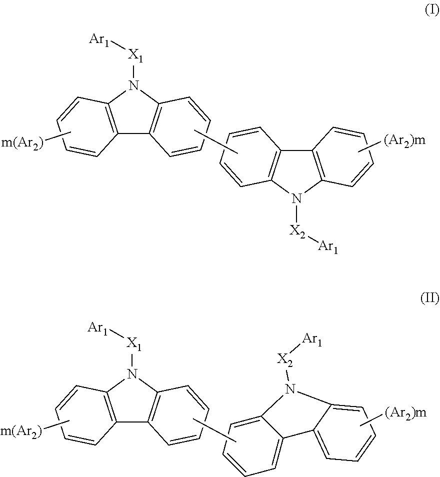

where X₁ and X₂ are the same or different, and are each independently selected from any one of a single bond, substituted or unsubstituted arylene in which a number of ring-forming carbon atoms is in a range from 6 to 30, and substituted or unsubstituted heteroarylene in which a number of ring-forming carbon atoms is in a range from 2 to 30; each Art is the same or different, and is independently selected from any one of hydrogen, deuterium, halogen, cyano, nitro, amino, substituted or unsubstituted alkyl in which a number of carbon atoms is in a range from 1 to 20, substituted or unsubstituted cycloalkyl in which a number of carbon atoms is in a range from 3 to 60, substituted or unsubstituted aryl in which a number of ring-forming carbon atoms is in a range from 6 to 60, and substituted or unsubstituted heteroaryl, in which a number of ring-forming carbon atoms is in a range from 2 to 60, containing at least one of O, S, N, and Si; each Are is the same or different, and is independently selected from any one of fluorine, cyano, substituted or unsubstituted alkyl in which a number of carbon atoms is in a range from 1 to 20, substituted or unsubstituted alkoxy in which a number of carbon atoms is in a range from 1 to 20, substituted or unsubstituted aryl in which a number of ring-forming carbon atoms is in a range from 6 to 30, and substituted or unsubstituted heteroaryl in which a number of ring-forming carbon atoms is in a range from 2 to 30; a substituent of X₁ or X₂ is selected from any one of alkyl in which a number of carbon atoms is in a range from 1 to 10, cycloalkyl in which a number of ring-forming carbon atoms is in a range from 3 to 20, aryl in which a number of ring-forming carbon atoms is in a range from 6 to 30, and heteroaryl, in which a number of ring-forming carbon atoms is in a range from 2 to 30, containing at least one of O, S, N, and Si; a substituent of Ar₁ is selected from any one of alkyl in which a number of carbon atoms is in a range from 4 to 6, cycloalkyl in which a number of ring-forming carbon atoms is in a range from 3 to 10, aryl in which a number of ring-forming carbon atoms is in a range from 6 to 30, and heteroaryl, in which a number of ring-forming carbon atoms is in a range from 2 to 30, containing at least one of O, S, N, and Si; a substituent of Ar₂ is selected from any one of alkyl in which a number of carbon atoms is in a range from 4 to 20, cycloalkyl in which a number of ring-forming carbon atoms is in a range from 3 to 10, aryl in which a number of ring-forming carbon atoms is in a range from 6 to 30, and heteroaryl, in which a number of ring-forming carbon atoms is in a range from 2 to 30, containing at least one of O, S, N, and Si; m is selected from any one of 0, 1 and 2.

In some embodiments, the first host material is selected from any one of following structures:

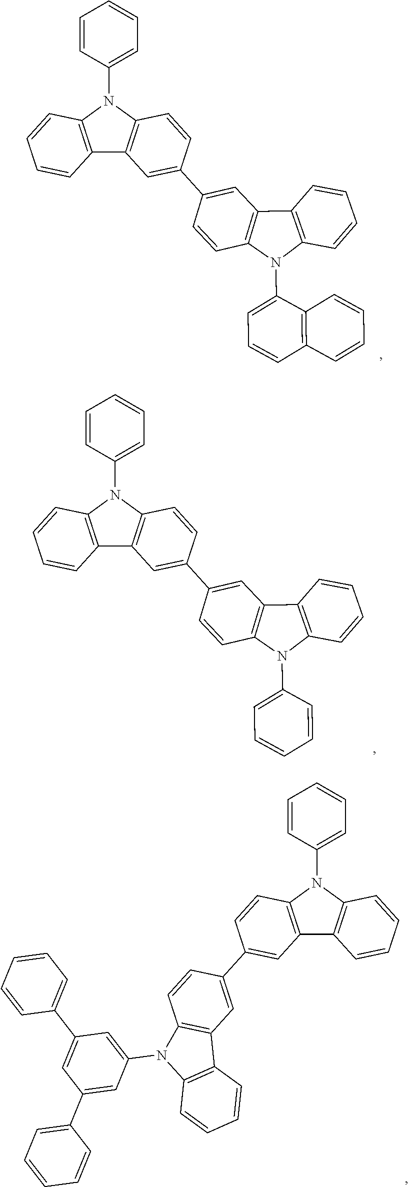

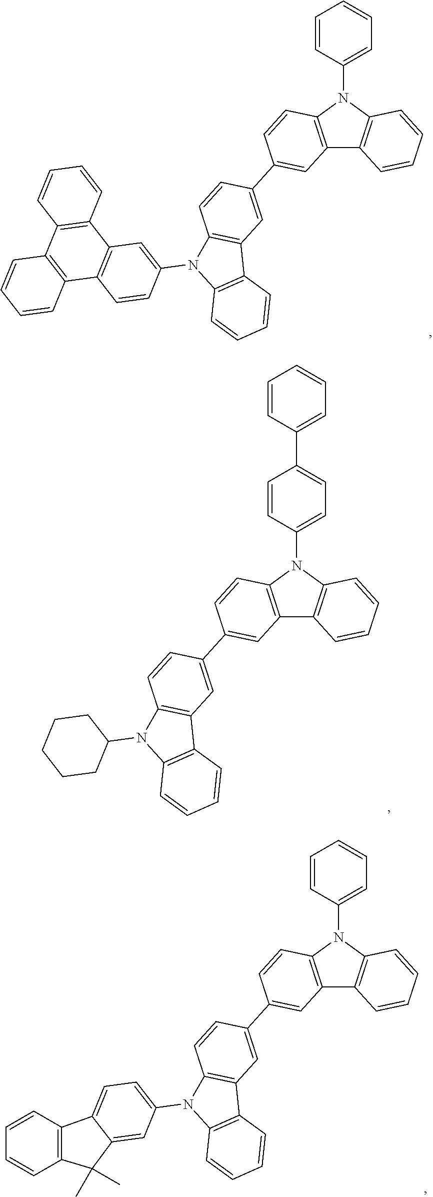 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-n3c4ccccc4c4cc(-c5ccc6c(c5)c5ccccc5n6C5CCCCC5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21]

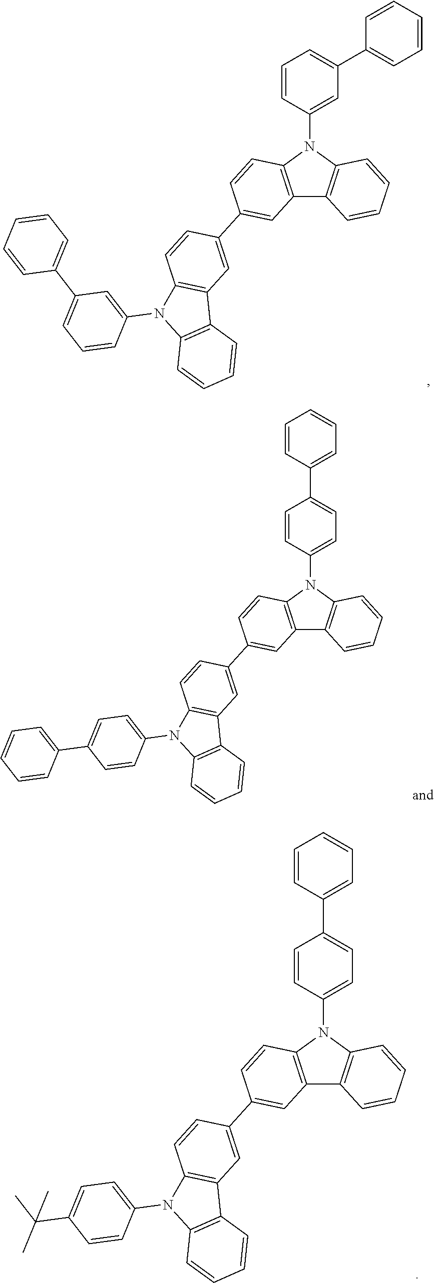 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; CC(C)(C)c1ccc(-n2c3ccccc3c3cc(-c4ccc5c(c4)c4ccccc4n5-c4ccc(-c5ccccc5)cc4)ccc32)cc1]

in some embodiments, the second host material is selected from structures represented by a following general formula (III):

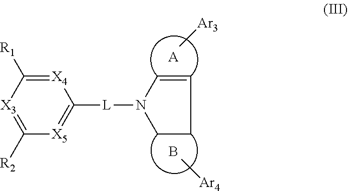

where X₃, X₄ and X₅ are each independently selected from N or CR₃, and at least one of X₃ to X₅ is N; L is selected from any one of a single bond, substituted or unsubstituted alkyl in which a number of carbon atoms is in a range from 1 to 20, substituted or unsubstituted arylene in which a number of carbon atoms is in a range from 6 to 30, and substituted or unsubstituted heteroarylene, in which a number of carbon atoms is in a range from 2 to 60, containing at least one of O, S, N, and Si; A and B are each independently selected from any one of an aromatic ring in which a number of ring-forming carbon atoms is in a range from 6 to 30, and a heteroaromatic ring in which a number of ring-forming carbon atoms is in a range from 2 to 30; Ar₃ and Ar₄ are each independently selected from any one of substituted or unsubstituted alkyl in which a number of carbon atoms is in a range from 2 to 20, substituted or unsubstituted aryl in which a number of ring-forming carbon atoms is in a range from 6 to 60, and substituted or unsubstituted heteroaryl in which a number of ring-forming carbon atoms is in a range from 6 to 60; R₁, R₂ and R₃ are each independently selected from any one of hydrogen, substituted or unsubstituted alkyl in which a number of carbon atoms is in a range from 2 to 20, substituted or unsubstituted aryl in which a number of carbon atoms is in a range from 6 to 60, and substituted or unsubstituted heteroaryl, in which a number of carbon atoms is in a range from 6 to 60, containing at least one of O, S, N, and Si; substituents of L, Ar₃, Ar₄, R₁, R₂ and R₃ are each independently selected from any one or more of halogen, cyano, alkyl, aryl and heteroaryl.

In some embodiments, the second host material is selected from any one of following structures:

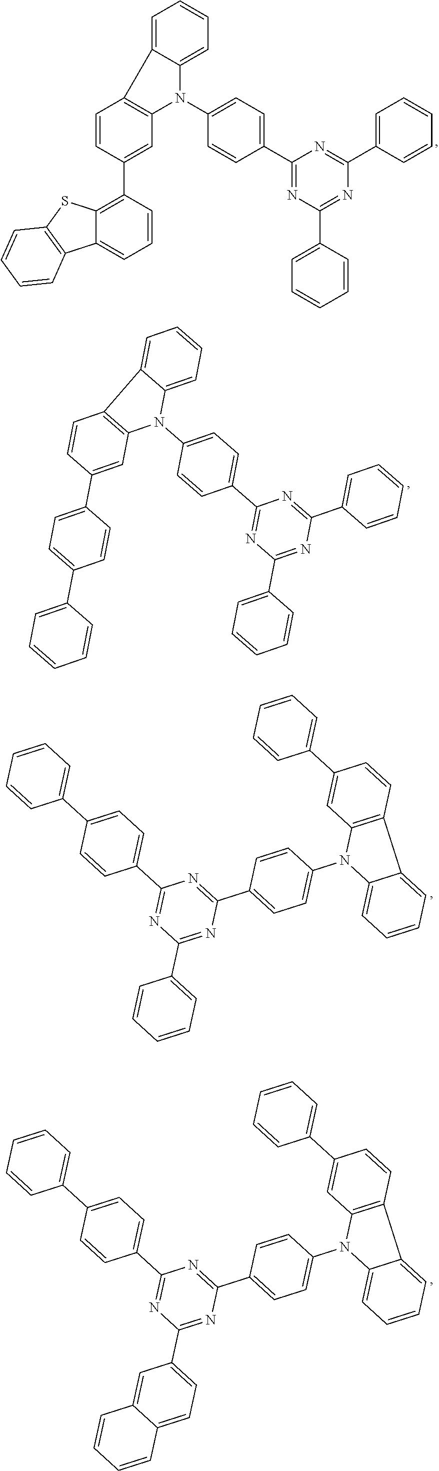 [SMILES: c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2ccc(-c3ccc4c5ccccc5n(-c5ccc(-c6nc(-c7ccccc7)nc(-c7ccccc7)n6)cc5)c4c3)cc2)cc1 ; c1ccc(-c2ccc(-c3nc(-c4ccccc4)nc(-c4ccc(-n5c6ccccc6c6ccc(-c7ccccc7)cc65)cc4)n3)cc2)cc1 ; c1ccc(-c2ccc(-c3nc(-c4ccc(-n5c6ccccc6c6ccc(-c7ccccc7)cc65)cc4)nc(-c4ccc5ccccc5c4)n3)cc2)cc1]

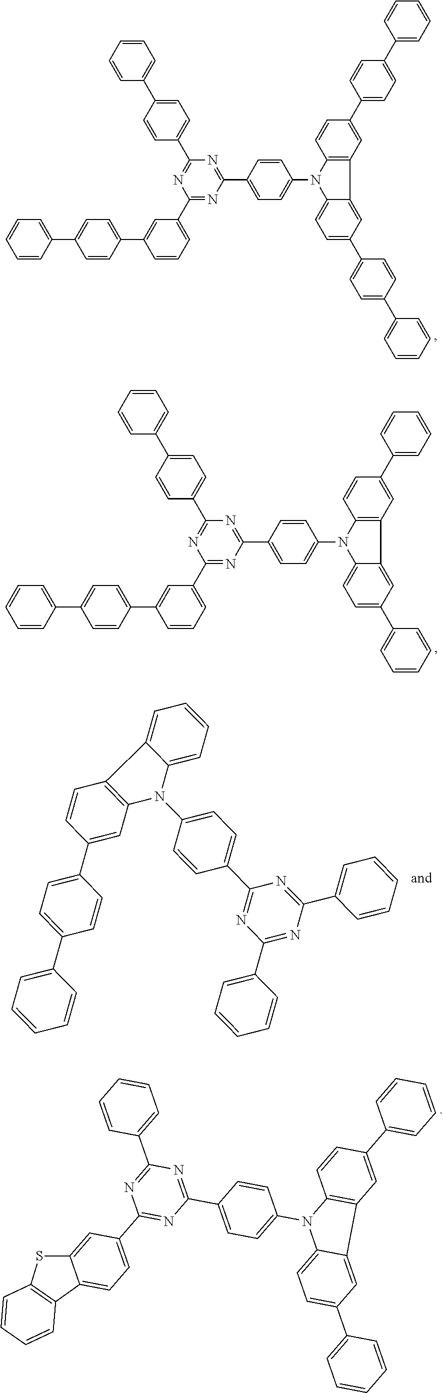 [SMILES: c1ccc(-c2ccc(-c3cccc(-c4nc(-c5ccc(-c6ccccc6)cc5)nc(-c5ccc(-n6c7ccc(-c8ccc(-c9ccccc9)cc8)cc7c7cc(-c8ccc(-c9ccccc9)cc8)ccc76)cc5)n4)c3)cc2)cc1 ; c1ccc(-c2ccc(-c3cccc(-c4nc(-c5ccc(-c6ccccc6)cc5)nc(-c5ccc(-n6c7ccc(-c8ccccc8)cc7c7cc(-c8ccccc8)ccc76)cc5)n4)c3)cc2)cc1 ; c1ccc(-c2ccc(-c3ccc4c5ccccc5n(-c5ccc(-c6nc(-c7ccccc7)nc(-c7ccccc7)n6)cc5)c4c3)cc2)cc1 ; c1ccc(-c2ccc3c(c2)c2cc(-c4ccccc4)ccc2n3-c2ccc(-c3nc(-c4ccccc4)nc(-c4ccc5c(c4)sc4ccccc45)n3)cc2)cc1]

In some embodiments, the light-emitting device that emits the green light further includes a hole transporting layer disposed between the first electrode and the light-emitting layer and an electron transporting layer disposed between the second electrode and the light-emitting layer. A material of the hole transporting layer is selected from any one or more of a carbazole compound, hexaazatriphenylenehexacabonitrile, 2,3,5,6-Tetrafluoro-7,7′,8,8′-tetracyanoquinodimethane and 1,2,3-tris[(cyano)(4-cyano-2,3,5,6-tetrafluorophenyl)methylene]cyclopropane. A material of the electron transporting layer is selected from compounds containing any one or more groups of triazine, pyridine, azine and benzimidazole.

In some embodiments, the light-emitting layer further includes a guest material, and the guest material is selected from one or more of following structures:

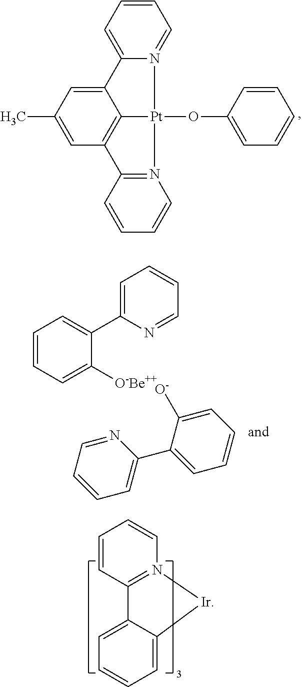

In some embodiments, the first electrode is an anode, and a material of the anode is selected from high work function materials.

In some embodiments, the second electrode is a cathode, and a material of the cathode is selected from low work function materials.

In another aspect, a light-emitting substrate is provided. The light-emitting substrate includes a substrate and a plurality of light-emitting devices disposed on the substrate. At least one light-emitting device is the light-emitting device that emits the green light as described above.

In some embodiments, under a test condition where an electric field intensity is 5000 V^{1/2}/m^{1/2}, the hole mobility of the first host material is in a range from 1×10⁻⁸ cm²V⁻¹s⁻¹ to 1×10⁻⁶ cm²V⁻¹s⁻¹, inclusive, and the electron mobility of the second host material is in a range from 1×10⁻⁹ cm²V⁻¹s⁻¹ to 1×10⁻⁶ cm²V⁻¹s⁻¹, inclusive.

In some embodiments, the LUMO energy level of the first host material is in a range from −2.4 eV to −2.0 eV, inclusive; the LUMO energy level of the second host material is in a range from −3.0 eV to −2.7 eV, inclusive.

In some embodiments, a full width at half maximum of an emission spectrum of the exciplex is greater than or equal to 90 nm.

In some embodiments, the first host material is selected from structures each having two carbazoles.

In yet another aspect, a light-emitting apparatus is provided. The light-emitting apparatus includes the light-emitting substrate as described above.

### BRIEF DESCRIPTION OF THE DRAWINGS

In order to describe technical solutions in the present disclosure more clearly, accompanying drawings to be used in some embodiments of the present disclosure will be introduced briefly below, Obviously, the accompanying drawings to be described below are merely accompanying drawings of some embodiments of the present disclosure, and a person of ordinary skill in the art can obtain other drawings according to these drawings. In addition, the accompanying drawings in the following description may be regarded as schematic diagrams, and are not limitations on actual sizes of products, actual processes of methods and actual timings of signals involved in the embodiments of the present disclosure.

FIG. 1 is a sectional view light-emitting substrate, in accordance with some embodiments;

FIG. 2 is a top view of a light-emitting substrate, in accordance with some embodiments;

FIG. 3 is a comparison diagram of distributions, at different temperatures, of exciton intensities in a light-emitting layer provided in the related art;

FIG. 4 is a diagram showing a corresponding relationship between a temperature and a ratio of an electron mobility to a hole mobility of an entire light-emitting device provided in the related art;

FIG. 5 is a diagram showing an energy level relationship among a first host material, a second host material, an electron blocking layer and a hole blocking layer, in accordance with some embodiments; and

FIG. 6 is a comparison diagram of normalized emission spectra of a first host material, a second host material and an exciplex formed by the first host material and the second host material, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A. B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

Additionally, the phase “based on” as used herein is meant to be open and inclusive, since a process, a step, a calculation or other action that is “based on” one or more of the stated conditions or values may, in practice, be based on additional conditions or values beyond those stated.

As used herein, the term such as “about” or “approximately” includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

Some embodiments of the present disclosure provide a light-emitting apparatus. The light-emitting apparatus includes a light-emitting substrate, and may, of course, further include other components. For example, the other components may include a circuit used for providing an electrical signal for the light-emitting substrate to drive the light-emitting substrate to emit light. The circuit may be referred to as a control circuit. The other components may include a circuit board and/or an integrated circuit (IC) each electrically connected to the light-emitting substrate.

In some embodiments, the light-emitting apparatus may be a lighting apparatus; in this case, the light-emitting apparatus serves as a light source for realizing a lighting function. For example, the light-emitting apparatus may be a backlight module in a liquid crystal display apparatus, a lamp used for internal or external lighting or a lamp in various signal lamps.

In some other embodiments, the light-emitting apparatus may be a display apparatus. In this case, the light-emitting substrate is a display substrate for realizing a function of displaying images (i.e., pictures). The light-emitting apparatus may include a display or a product including the display. The display may be a flat panel display (FPD), a micro display, etc. The display may be classified as a transparent display or a non-transparent display according to whether a user can see a scene behind the display. The to display may be classified as a flexible display or a normal display (which may be referred to as a rigid display) according to whether the display can be bent or rolled. For example, the product including the display may include a computer display, a television, a billboard, a laser printer having a display function, a telephone, a mobile phone, a personal digital assistant (FDA), a laptop computer, a digital camera, a portable camcorder, a viewfinder, a vehicle, a large-area wall, a screen of a theater or a sign of a stadium.

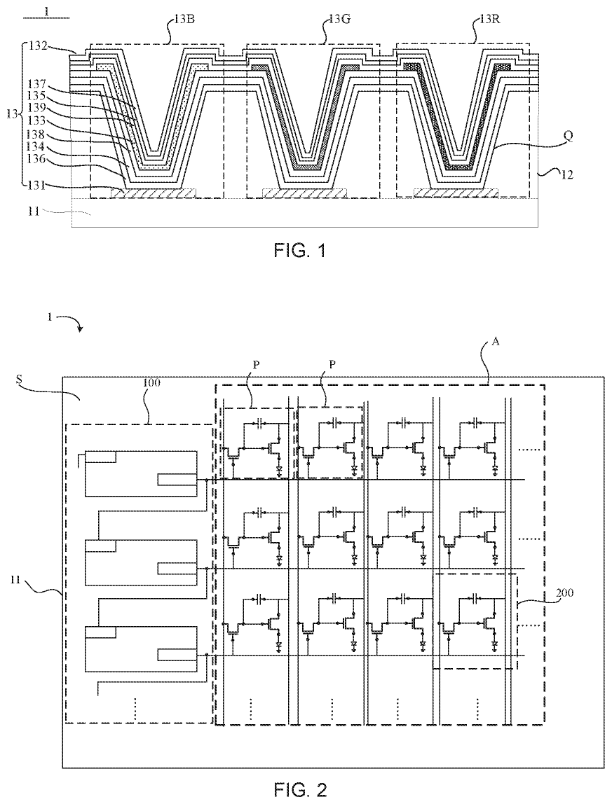

Some embodiments of the present disclosure provide a light-emitting substrate 1, as shown in FIG. 1, the light-emitting substrate 1 includes a substrate 11, and a pixel definition layer 12 and a plurality of light-emitting devices 13 that are disposed on the substrate 11, The pixel definition layer 12 has a plurality of openings Q, and the plurality of light-emitting devices 13 may be arranged in a one-to-one correspondence with the plurality of openings Q. Here, the plurality of light-emitting devices 13 may be all or part of light-emitting devices 13 included in the light-emitting substrate 1; the plurality of openings Q may be all or part of openings in the pixel definition layer 12.

In the plurality of light-emitting devices 13, at least one light-emitting device 13 may include a first electrode 131, a second electrode 132, and a light-emitting layer 133 disposed between the first electrode 131 and the second electrode 132. Each light-emitting layer 133 may include a portion located in an opening Q.

In some embodiments, as shown in FIG. 1, the first electrode 131 may be an anode; in this case, the second electrode 132 is a cathode. In some other embodiments, the first electrode 131 may be a cathode; in this case, the second electrode 132 is an anode.

In some embodiments, a material of the anode may be selected from high work function materials such as transparent conductive materials (e.g., indium tin oxide (ITO), indium zinc oxide (IZO), tin dioxide (SnO₂), zinc oxide (ZnO)), metal materials (e.g., silver (Ag) and alloys thereof, aluminum (Al) and alloys thereof), organic conductive materials (e.g., poly(3,4-ethylenedioxythiophene) (PEDOT)) or composite materials of the above materials (e.g., Ag/ITO, Al/ITO, Ag/IZO or AI/IZO). “Ag/ITO” refers to a stacked structure in which a silver electrode and an ITO electrode are stacked. A material of the cathode may be selected from low work function materials (e.g., lithium fluoride (LiF)/Al, Al, Ag or magnesium (Mg)) or low work function metal alloy materials (e.g., Mg—Al alloy, Mg—Ag alloy), “LiF/Al” refers to a stacked structure in which Al and LiF are stacked.

For an organic light-emitting diode (OLED) light-emitting device, a light-emitting principle of the light-emitting device 13 is that, through a circuit connected between the anode and the cathode, the anode injects holes into the light-emitting layer 133, the cathode injects electrons into the light-emitting layer 133, the electrons and the holes that are injected form excitons in the light-emitting layer 133, and the excitons are back to a ground state through a manner of radiative transition, so as to emit photons.

As shown in FIG. 1, in order to improve an efficiency of injecting the electrons and the holes into the light-emitting layer 133, the light-emitting device 13 may further include at least one of a hole transporting layer (HTL) 134, an electron transporting layer (ETL) 135, a hole injection layer (HIL) 136 and an electron injection layer (EIL) 137. For example, the light-emitting device 13 may further include the hole transporting layer (HTL) 134 disposed between the anode and the light-emitting layer 133, and the electron transporting layer (ETL) 135 disposed between the cathode and the light-emitting layer. In order to further improve the efficiency of injecting the electrons and the holes into the light-emitting layer 133, the light-emitting device 13 may further include the hole injection layer (HIL) 136 disposed between the anode and the hole transporting layer 134, and the electron injection layer (EIL) 137 disposed between the cathode and the electron transporting layer 135.

In some embodiments, a material of the electron transporting layer 135 may be selected from organic materials having good electron transmission properties. For example, the material of the electron transporting layer 135 may be a compound, having a high electron mobility, containing triazine, pyridine, azine or benzimidazole. Alternatively, the material of the electron transporting layer 135 may be selected from organic materials doped with LiQ₃, lithium (Li), calcium (Ca) or the like. A thickness of the electron transporting layer 135 may be in a range from 10 nm to 70 nm, inclusive. A material of the hole transporting layer 134 may be selected from materials each having a relatively high hole mobility such as any one of a carbazole compound, hexaazatriphenylenehexacabonitrile (HATCN), 6,5,6-Tetrafluoro-7,7′,8,8′-tetracyanoquinodimethane (F4TCNQ) and 1,2,3-tris[(cyano)(4-cyano-2,3,5,6-tetrafluorophenyl)methylene]cyclopropane or a combine of two or more thereof.

In some other embodiments, a material of the electron injection layer 137 may be selected from low work function metals such as Li, Mg, Ca and ytterbium (Yb);

alternatively, the material of the electron injection layer 137 may be selected from metal salts such as LiF and LiQ₃. A thickness of the electron injection layer 137 may be in a range from 0.5 nm to 2 nm, inclusive. A material of the hole injection layer 136 may be selected from copper(II) phthalocyanine (CuPc), hexaazatriphenylenehexacabonitrile (HATCN) or manganese trioxide (MnO₃). Alternatively, the material of the hole injection layer 136 may be selected from materials obtained by performing P-type doping on these materials. A thickness of the hole injection layer 136 may be in a range from 5 nm to 30 nm, inclusive.

In a process of transporting the holes and the electrons, in order to avoid a problem that a reduction, caused by a fact that the electrons are quenched on a surface of the anode and the holes are quenched on a surface of the cathode, of a recombination efficiency of the electrons and the holes is not conducive to an improvement of a luminous efficiency. In some embodiments, as shown in FIG. 1, the light-emitting device 13 further includes an electron blocking layer (EBL) 138 located between the hole transporting layer 134 and the light-emitting layer 133, and a hole blocking layer (HBL) 139 located between the electron transporting layer 135 and the light-emitting layer 133.

In some embodiments, a material of the electron blocking layer 138 may be selected from any one of 4,4′-cyclohexylidenebis[N,N-bis(p-tolyl)aniline] and 4,4′,4″-Tris(carbazol-9-yl)-triphenylamine. 2,9-dimethyl-4,?-diphenyl-1,10-Phenanthroline may be selected as a material of the hole blocking layer (HBL) 139.

The light-emitting substrate 1 may be further provided with a driving circuit connected to all light-emitting devices 13 therein, and the driving circuit may be connected to the control circuit to drive each light-emitting device 13 to emit light according to a respective electrical signal input by the control circuit. The driving circuit may be an active driving circuit or a passive driving circuit.

The light-emitting substrate 1 may emit white light, monochromatic light (i.e., single-color light) or color-tunable light.

In a first example, the light-emitting substrate 1 may emit the white light. In this case, as shown in FIG. 1, the plurality of light-emitting devices 13 may include a light-emitting device 13B that emits blue light, a light-emitting device 13R that emits red light and a light-emitting device 13G that emits green light. In this case, the light-emitting device 13B that emits the blue light, the light-emitting device 13R that emits the red light and the light-emitting device 13G that emits the green light are controlled to emit light simultaneously, which may achieve light mixing of the light-emitting device 13B that emits the blue light, the light-emitting device 13R that emits the red light and the light-emitting device 13G that emits the green light, thereby enabling the light-emitting substrate 1 to emit the white light.

In this example, the light-emitting substrate 1 may be used for lighting. That is, the light-emitting substrate 1 may be applied to a lighting apparatus.

In a second example, the light-emitting substrate 1 may emit the monochromatic light. In this case, considering an example in which the plurality of light-emitting devices 13 are each the light-emitting device 13G that emits the green light, in this example, the light-emitting substrate 1 may be used for lighting. That is, the light-emitting substrate 1 may be applied to a lighting apparatus. Alternatively, the light-emitting substrate 1 may be used for displaying images or pictures of a single color. That is, the light-emitting substrate 1 may be applied to a display apparatus.

In a third example, the light-emitting substrate 1 may emit the color-tunable light (i.e., colored light). The plurality of light-emitting devices 13 included in the light-emitting substrate 1 are similar to the plurality of light-emitting devices 13 as described in the first example in structure. A color and luminance of mixed light emitted by the light-emitting substrate 1 may be controlled by controlling luminance of each light-emitting device 13, thereby achieving emitting the colored light.

In this example, the light-emitting substrate 1 may be used for displaying images or pictures. That is, the light-emitting substrate 1 may be applied to a display apparatus. Of course, the light-emitting substrate 1 may be applied to a lighting apparatus.

In the third example, in an example where the light-emitting substrate 1 is a display substrate such as a full color display panel, as shown in FIG. 2, the light-emitting substrate 1 includes a display area A and a peripheral area S disposed around the display area A, The display area A includes a plurality of sub-pixel regions P. Each sub-pixel region P corresponds to an opening, and an opening corresponds to a light-emitting device. Each sub-pixel region P is provided with a pixel driving circuit 200 used for driving a respective light-emitting device to emit light therein. The peripheral region S is used for wiring. For example, the peripheral region S is used for arranging a gate driving circuit 100 connected to the pixel driving circuits 200.

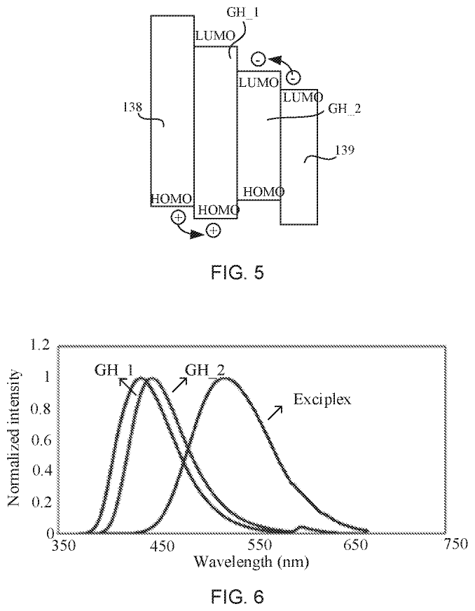

In some embodiments, in the plurality of light-emitting devices 13, at least one light-emitting device 13 is a light-emitting device that emits green light. A light-emitting layer 133 in the light-emitting device that emits the green light includes a host material (GH) and a guest material (GB). As shown in FIGS. 5 and 6, the host material (GH) is a dual-host material that includes a first host material GH_1 and a second host material GH_2. and the first host material GH_1 and the second host material GH_2 form an exciplex. A difference between a lowest unoccupied molecular orbital (LUMO) energy level of the first host material GH_1 and a LUMO energy level of the second host material GH_2 is greater than or equal to 0.5 eV; under a same test condition, a difference between an order of magnitude of a hole mobility of the first host material GH_1 and an order of magnitude of an electron mobility of the second host material GH_1 is greater than or equal to 1.

The host material is a material having characteristics of a capability to transfer energy with the guest material, a reversible electrochemical redox reaction, a good and matched capability to transport holes and electrons, a good thermal stability and a good film-forming property, and the host material has a relatively large proportion in the light-emitting layer 133. The guest material may be, for example, a phosphor luminescent material, and the guest material has a relatively small proportion in the light-emitting layer 133.

The exciplex refers to an aggregation of two different molecules or atoms. In an excited state, the two different molecules or atoms have a relatively strong interaction and generate a new energy level, an emission spectrum of the aggregation is different from that of a single material, and the aggregation has no fine structure.

For example, the first host material GH_1 may be a p-type material that may be regarded as an electron donor material, the second host material GH_2 may be an n-type material that may be regarded as an electron acceptor material, and the exciplex is formed, under a condition of photo-excitation or electro-excitation, in a film formed by the first host material GH_1 and the second host material GH_2. In this case, the electron acceptor material in an excited state and the electron donor material in a ground state interact to form the exciplex in a charge-transfer state to emit light, and the exciplex has a new spectrum that is distinct from an emission spectrum of the first host material GH_1 and an emission spectrum of the second host material GH_2.

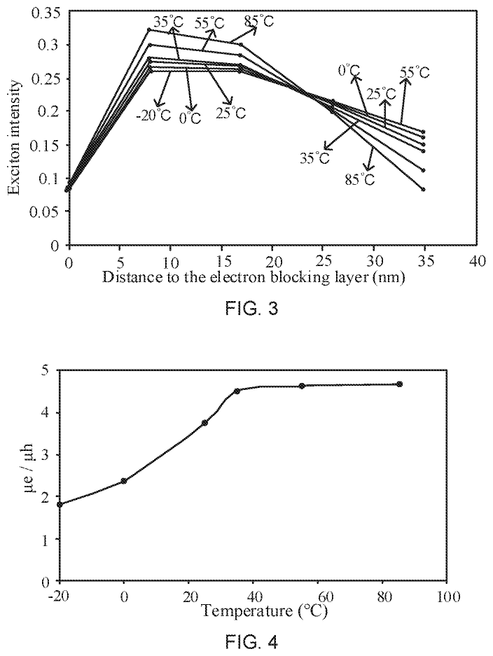

In a light-emitting device that emits green light in the related art, an electron mobility is greater than a hole mobility, so that a recombination region of the electrons and the holes is closer to a side of the light-emitting layer 133 proximate to the electron blocking layer 138. In addition, it can be found through experiments that a distribution, in the light-emitting layer 133, of exciton intensities generated by the recombination of the electrons and the holes is as shown in FIG. 3. It can be seen from FIG. 3 that an exciton intensity at the side of the light-emitting layer 133 proximate to the electron blocking layer 138 is the highest, and the exciton intensities gradually decrease as a position of the light-emitting layer 133 further away from the electron blocking layer 138.

Moreover, it can be found through experiments that, as for the light-emitting devices that emit the green light, in a case where the same material layer in different light-emitting devices is made of a same material, with reference to FIG. 4, as the temperature is increased, a ratio of the electron mobility (μe) of the light-emitting device 13 to the hole mobility (μh) of the light-emitting device 13 is increased; with reference to FIGS. 3 and 4, as the temperature is increased, the exciton intensity, at the side of the light-emitting layer 133 proximate to the electron blocking layer 138, is increased to a certain extent compared with that before the temperature is increased; and as a position of the light-emitting layer 133 further away from the electron blocking layer 138, the exciton intensities is reduced to a certain extent compared with that before the temperature is increased. It can be seen from above that, as the temperature is increased, a device efficiency of the light-emitting device 13 that emits the green light is reduced, which is caused by a fact that, as the temperature is increased, an exciton concentration in a portion, in which an original exciton concentration is relatively high, in the recombination region of the holes and the electrons is further increased, and an exciton concentration in a portion, in which an original exciton concentration is relatively low, in the recombination region of the holes and the electrons is further decreased, so that a distribution of exciton concentrations in the light-emitting layer is more unbalanced, and furthermore, as an exciton concentration at the side of the light-emitting layer 133 proximate to the electron blocking layer 138 is higher, the excitons (e.g., triplet excitons) are more prone to be quenched, so that a device stability and the device efficiency are reduced.

According to a fact that the electron donor material has a capability to transport the holes, and the electron acceptor material has a capability to transport the electrons, it can be seen that, as shown in FIG. 5, a highest occupied molecular orbital (HOMO) energy level of the first host material GH_1 is lower than a HOMO energy level of the second host material GH_2, and the LUMO energy level of the second host material GH_2 is lower than the LUMO energy level of the first host material GH_1, so that the holes are prone to transition from the electron blocking layer 138 or the hole transporting layer 134 to the HOMO energy level of the first host material GH_1 and the electrons are prone to transition from the hole blocking layer 139 or the electron transporting layer 135 to the LUMO energy level of the second host material GH_2. As a result, the electron acceptor material in the excited state and the electron donor material in the ground state interact to form the exciplex in the charge-transfer state to emit light, and an emission spectrum generated by the light emission of the exciplex in the charge-transfer state serves as an excitation spectrum of the guest material (GB) to excite the guest material (GB) to emit light, thereby achieving the light emission of the light-emitting device 13.

In the embodiments of the present disclosure, the difference between the LUMO energy level of the first host material GH_1 and the LUMO energy level of the second host material GH_2 is greater than or equal to 0.5 eV, so that in the process of transporting the electrons and the holes, a relatively large potential barrier (i.e. an electron trap) may be created between the LUMO energy level of the second host material GH_2 and the LUMO energy level of the first host material GH_1. Compared with the related art in which a difference between a LUMO energy level of a first host material and a LUMO energy level of a second host material is less than 0.5 eV, the electron mobility of the entire light-emitting device 13 in the embodiments of the present disclosure may be reduced, which makes the transport of the electrons and the holes tend to be balanced to adjust the recombination region of the electrons and the holes, so as to make the recombination region of the electrons and the holes move towards a side of the light-emitting layer 133 away from the electron blocking layer 138. In this way, a problem, caused by a fact that the exciton concentration at the side of the light-emitting layer 133 proximate to the electron blocking layer 138 is too high due to the increase of the temperature, that the device stability and the device efficiency are reduced may be counteracted or ameliorated.

In some embodiments, the LUMO energy level of the first host material GH_1 is in a range from −2.4 eV to −2.0 eV, inclusive; the LUMO energy level of the second host material GH_2 is in a range from −3.0 eV to −2.7 eV, inclusive.

In this case, in a case where the LUMO energy level of the first host material GH_1 is −2.4 eV, the LUMO energy level of the second host material GH_2 may be −2.9 eV or −3.0 eV; in a case where the LUMO energy level of the first host material GH_1 is −2.0 eV, the LUMO energy level of the second host material GH_2 may be any value in the range from −3.0 eV to −2.7 eV, inclusive; in a case where the LUMO energy level of the first host material GH_1 is −2.3 eV, the LUMO energy level of the second host material GH_2 may be −2.8 eV, −2.9 eV or −3.0 eV; in a case where the LUMO energy level of the first host material GH_1 is −2.2 eV, the LUMO energy level of the second host material GH_2 may be any value in the range from −3.0 eV to −2.7 eV, inclusive; in a case where the LUMO energy level of the first host material GH_1 is −2.1 eV, the LUMO energy level of the second host material GH_2 may be any value in the range from −3.0 eV to −2.7 eV, inclusive.

An order of magnitude refers to a level or a scale of magnitude, and the levels of the magnitude remain a constant ratio therebetween. A single-digit number less than 10 (e.g., a number of 1 to 9) is in an order of magnitude. A double-digit number (e.g., 12 or 18) is in another order of magnitude. The double-digit number is one order of magnitude greater than the single-digit number. By analogy, a triple-digit number is one order of magnitude greater than the double-digit number, and is two orders of magnitude greater than the single-digit number.

Orders of magnitude may be regarded as a series of powers of 10. In a case where a numerical value is represented by an order of magnitude, the numerical value is typically represented in a form of a×10^{b}; where “a” is any value greater than or equal to 1 and less than 10. For example, “a” may be an integer in a range from 1 to 9, inclusive; alternatively, “a” may be a decimal greater than 1 and less than 10, such as 1.5, 2.5, 4.5, 6.8 and 7,9. “b” of “10^{b}” represents the order of magnitude.

In the embodiments of the present disclosure, under a same test condition, the difference between the order of magnitude of the hole mobility of the first host material GH_1 and the order of magnitude of the electron mobility of the second host material GH_2 is greater than or equal to 1, which refers to that, under a same test condition, the order of magnitude of the hole mobility of the first host material GH_1 minus the order of magnitude of the electron mobility of the second host material GH_2 is greater than or equal to 1.

The same test condition refers to a test condition where a test sample is different, and other conditions are each the same.

In some embodiments, under a test condition where an electric field intensity is 5000 V^{1/2}/m^{1/2}, the hole mobility of the first host material GH_1 is in a range from 1×10⁻⁸ cm²V⁻¹s⁻¹ to 1×10⁻⁶ cm²V⁻¹s⁻¹, inclusive, and an electron mobility of the second host material GH_2 is in a range from 1×10⁻⁹ cm²V⁻¹s⁻¹ to 1×10⁻⁶ cm²V⁻¹s⁻¹, inclusive.

Here, the same test condition refers to the test condition where the electric field intensity is 5000 V^{1″2}/m^{1/2}. A manner for testing the mobility may be selected from any one of a time-of-flight (TOF) manner and a space-charge limited current (SOLO) method.

In this case, in a case where the difference between the order of magnitude of the hole mobility of the first host material GH_1 and the order of magnitude of the electron mobility of the second host material GH_2 is equal to 1, in an example where the hole mobility, under the test condition where the electric field intensity is 5000 V^{1/2}/m^{1/2}, of the first host material GH_1 is 5×10⁻⁸ cm²V⁻¹s⁻¹ the electron mobility of the second host material GH_2 may be 1×10⁻⁹ cm²V⁻¹s⁻¹, 2×10⁻⁹ cm²V⁻¹s⁻¹, 3×10⁻⁹ cm²V⁻¹s⁻¹, 4×10⁻⁹ cm²V⁻¹s⁻¹, 5×10⁻⁹ cm²V⁻¹s⁻¹, 6×10⁻⁹ cm²V⁻¹s⁻¹, 7×10⁻⁹ cm²V⁻¹s⁻¹, 8×10⁻⁹ cm²V⁻¹s⁻¹ or 9×10⁻⁹ cm²V⁻¹s⁻¹.

In a case where the difference between the order of magnitude of the hole mobility of the first host material GH_1 and the order of magnitude of the electron mobility of the second host material GH_2 is greater than 1, in an example where the hole mobility, under the test condition where the electric field intensity is 5000 V^{1/2}/m^{1/2}, of the first host material GH_1 is 5×10⁻⁷ cm²V⁻¹s⁻¹, the electron mobility of the second host material GH_2 may be 1×10⁻⁹ cm²V⁻¹s⁻¹, 2×10⁻⁹ cm²V⁻¹s⁻¹, 3×10⁻⁹ cm²V⁻¹s⁻¹, 4×10⁻⁹ cm²V⁻¹s⁻¹, 5×10⁻⁹ cm²V⁻¹s⁻¹, 6×10⁻⁹ cm²V⁻¹s⁻¹, 7×10⁻⁹ cm²V⁻¹s⁻¹, 8×10⁻⁹ cm²V⁻¹s⁻¹ or 9×10⁻⁹ cm²V⁻¹s⁻¹. In this case, the difference between the order of magnitude of the hole mobility of the first host material GH_1 and the order of magnitude of the electron mobility of the second host material GH_2 is equal to 2, i.e., a result of −7 minus −9. In an example where the hole mobility, under the test condition where the electric field intensity is 5000 V^{1/2}/m^{1/2}, of the first host material GH_1 is 5×10⁻⁶ cm²V⁻¹s⁻¹ the electron mobility of the second host material GH_2 may be 1×10⁻⁶ cm²V⁻¹s⁻¹, 2×10⁻³ cm²V⁻¹s⁻¹, 3×10⁻⁶ cm²V⁻¹s⁻¹, 4×10⁻⁶ cm²V⁻¹s⁻¹, 5×10⁻⁶ cm²V⁻¹s⁻¹, 6×10⁻⁶ cm²V⁻¹s⁻¹, 7×10⁻⁸ cm²V⁻¹s⁻¹, 8×10⁻⁸ cm²V⁻¹s⁻¹ or 9×10⁻⁸ cm²V⁻¹s⁻¹. In this case, the difference between the order of magnitude of the hole mobility of the first host material GH_1 and the order of magnitude of the electron mobility of the second host material GH_2 is equal to 2, i.e., a result of −6 minus −8.

In the embodiments of the present disclosure, in a case where the difference between the LUMO energy level of the first host material GH_1 and the LUMO energy level of the second host material GH_2 is determined (e.g., greater than or equal to 0.5 eV), the first host material GH_1 having the relatively high hole mobility and the second host material GH_2 having the relatively low electron mobility are provided, so as to further improve the hole mobility of the entire light-emitting device 13 and reduce the electron mobility of the entire light-emitting device 13. As a result, it is possible to further adjust the recombination region of the electrons and the holes, which makes the recombination region of the electrons and the holes move towards the side of the light-emitting layer 133 away from the electron blocking layer 138, so that the problem, caused by the fact that the exciton concentration at the side of the light-emitting layer 133 proximate to the electron blocking layer 138 is too high due to the increase of the temperature, that the device stability and the device efficiency are reduced may be further counteracted or ameliorated.

In some embodiments, the light-emitting layer further includes the guest material, and the guest material is selected from one or more of following structures:

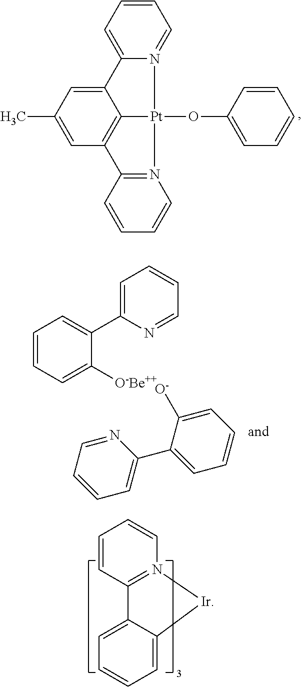

In some embodiments, as shown in FIG. 6, a full width at half maximum of the emission spectrum of the exciplex is greater than or equal to 90 nm.

According to a fact that the guest material (GB) is excited by the emission spectrum of the exciplex to emit light, it can be seen that, in a case where the guest material (GB) is determined, the greater an integral area of an overlapping region between a normalized emission spectrum of the exciplex and a normalized absorption spectrum of the guest material (GB), the more sufficient the Forster energy transfer between the host material (GH) and the guest material (GB). Based on this, in the embodiments of the present disclosure, the exciplex having the emission spectrum of which the wavelength is in a suitable range and the full width at half maximum is made as large as possible is provided. Compared with an exciplex having an emission spectrum of which a full width at half maximum is relatively all, in the embodiments of the present disclosure, the integral area of the overlapping region between the normalized emission spectrum of the exciplex and the normalized absorption spectrum of the guest material (GB) may be improved, so that the Forster energy transfer between the host material (GH) and the guest material (GB) may be made as sufficient as possible.

For example, in some embodiments, as shown in FIG. 6, the full width at half maximum of the emission spectrum of the exciplex is in a range from 100 nm to 110 nm, inclusive. The exciplex of which the full width at half maximum is in this range may meet utilization requirements.

In some embodiments, the first host material GH_1 is selected from structures each having two carbazoles. The carbazole has a relatively good property of transporting holes. A hole transport rate may be effectively improved by selecting a structure having two carbazoles, thereby improving the hole mobility.

In some embodiments, the first host material GH_1 is selected from structures represented by following general formula (I) and general formula (II).

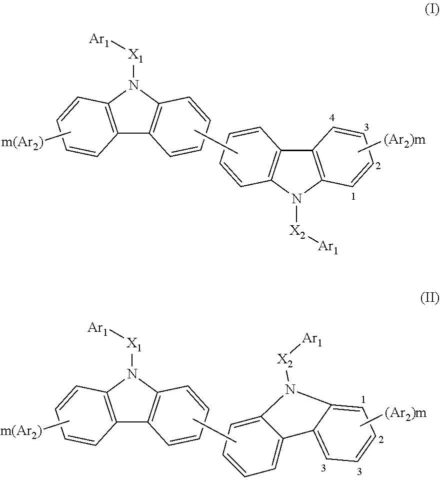

X₁ and X₂ are the same or different, and are each independently selected from any one of a single bond, substituted or unsubstituted arylene in which the number of ring-forming carbon atoms is in a range from 6 to 30, and substituted or unsubstituted heteroarylene in which the number of ring-forming carbon atoms is in a range from 2 to 30.

Each Ar₁ is the same or different, and is independently selected from any one of hydrogen, deuterium, halogen, cyano, nitro, amino, substituted or unsubstituted alkyl in which the number of carbon atoms is in a range from 1 to 20, substituted or unsubstituted cycloalkyl in which the number of carbon atoms is in a range from 3 to 60, substituted or unsubstituted aryl in which the number of ring-forming carbon atoms is in a range from 6 to 60, and substituted or unsubstituted heteroaryl, in which the number of ring-forming carbon atoms is in a range from 2 to 60, containing at least one of O, S, N, and Si.

Each Are is the same or different, and is independently selected from any one of fluorine, cyano, substituted or unsubstituted alkyl in which the number of carbon atoms is in a range from 1 to 20, substituted or unsubstituted alkoxy in which the number of carbon atoms in a range from 1 to 20, substituted or unsubstituted aryl in which the number of ring-forming carbon atoms is in a range from 6 to 30, and substituted or unsubstituted heteroaryl in which the number of ring-forming carbon atoms is in a range from 2 to 30.

A substituent of X₁ or x₂ is selected from any one of alkyl in which the number of carbon atoms is in a range from 1 to 10, cycloalkyl in which the number of ring-forming carbon atoms is in a range from 3 to 20, aryl in which the number of ring-forming carbon atoms is in a range from 6 to 30, and heteroaryl, in which the number of ring-forming carbon atoms is in a range from 2 to 30, containing at least one of O, S, N, and Si.

A substituent of Ar₁ is selected from any one of alkyl in which the number of carbon atoms is in a range from 4 to 6, cycloalkyl in which the number of ring-forming carbon atoms is in a range from 3 to 10, aryl in which the number of ring-forming carbon atoms is in a range from 6 to 30, and heteroaryl, in which the number of ring-forming carbon atoms is in a range from 2 to 30, containing at least one of O, 5, N, and Si; a substituent of Ar₂ is selected from any one of alkyl in which the number of carbon atoms is in a range from 4 to 20, cycloalkyl in which the number of ring-forming carbon atoms is in a range from 3 to 10, aryl in which the number of ring-forming carbon atoms is in a range from 6 to 30, and heteroaryl, in which the number of ring-forming carbon atoms is in a range from 2 to 30, containing at least one of O, S, N, and Si; m is selected from any one of 0, 1 and 2.

In organic chemistry; the term “aryl” refers to any functional group or substituent derived from a simple aromatic ring, and is a general term for a monovalent radical derived from an aromatic hydrocarbon molecule by a removal of one hydrogen atom from a carbon atom of the aromatic nucleus. The simplest aryl is phenyl, which is derived from benzene. The phenyl is monocyclic aryl. Of course; in addition to monocyclic aryl, aryl may also include polycyclic aryl and fused ring aryl.

The term “heteroaryl” is a general term for a monovalent radical derived from a heterocyclic aromatic hydrocarbon molecule by a removal of one hydrogen atom from a carbon atom of the nucleus. For example, pyridyl and furyl are each monocyclic heteroaryl. Similar to aryl, in addition to monocyclic heteroaryl, heteroaryl may also include polycyclic heteroaryl and fused ring heteroaryl.

Correspondingly, the term “arylene” is a general term for a divalent radical derived from an aromatic hydrocarbon molecule by a removal of one hydrogen atom from each of two carbon atoms of the nucleus. Similar to aryl, arylene may include monocyclic arylene (e.g., divalent phenyl), polycyclic arylene (e.g., divalent biphenylene) and fused ring arylene (e.g., divalent naphthyl, divalent fluorenyl and divalent spirofluorenyl).

The term “heteroarylene” is a general term for a divalent radical derived from a heterocyclic aromatic hydrocarbon molecule by a removal of one hydrogen atom from each of two carbon atoms of the nucleus. Similar to heteroaryl, heteroarylene may include monocyclic heteroarylene (e.g., bivalent pyridyl), polycyclic heteroarylene (e.g., bivalent bigeminal pyridy and fused ring heteroarylene (e.g., divalent benzofuranyl and divalent carbazolyl).

The term “alkyl” is a general term for a monovalent radical derived from an alkane by a removal of one hydrogen atom from a carbon atom of the alkane.

The term “cycloalkyl” is a general term for a monovalent radical derived from a cycloalkane by a removal of one hydrogen atom from a carbon atom of the cycloalkane.

The term “alkoxy” is a general term for a monovalent radical derived from an alkane by removing one hydrogen atom from a carbon atom of the alkane and adding one oxygen atom on the carbon atom where the one hydrogen atom is removed.

In a case where the first host material GH_1 is selected from structures represented by the general formula (I), two carbazoles in the general formula (I) may be bonded through any one carbon atom of a benzene ring of one carbazole and any one carbon atom of a benzene ring of the other carbazole. For example, a bonding relationship between the two carbazoles may be represented by any one of following structures:

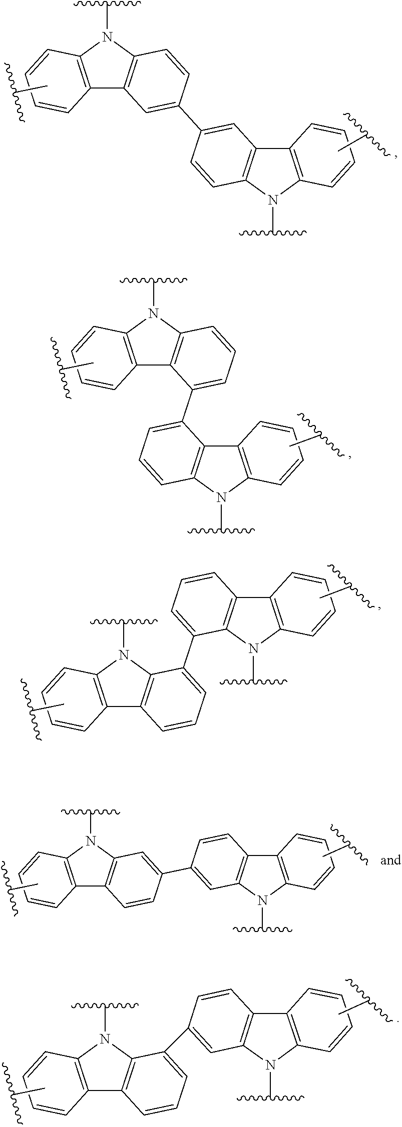

In a case where the first host material GH_1 is selected from structures represented by the general formula (H), two carbazoles in the general formula (H) may be bonded through any one carbon atom of a benzene ring of one carbazole and any one carbon atom of a benzene ring of the other carbazole. For example, a bonding relationship between the two carbazoles may be represented by any one of following structures:

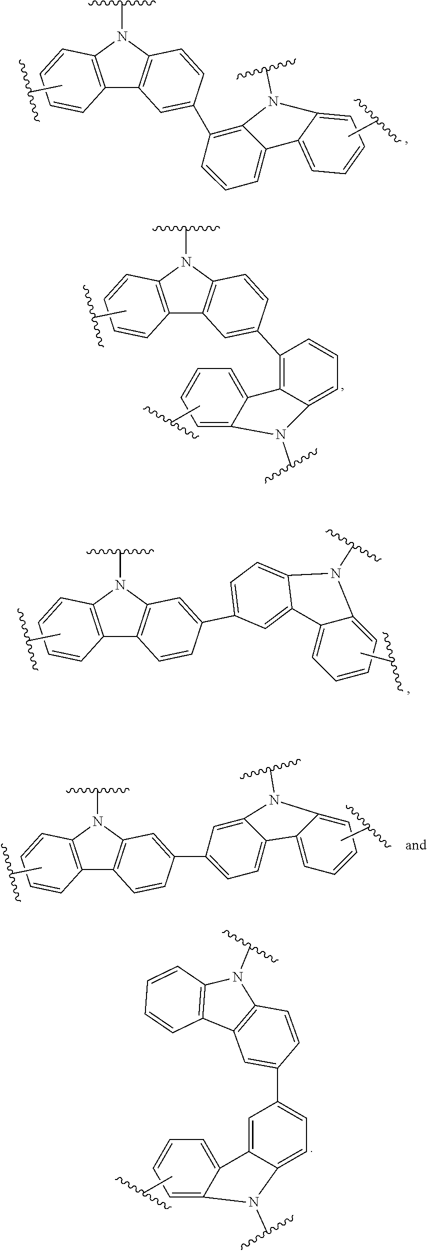

In the above formulas, [symbol] represents that a bonding structure is omitted.

In a case where X₁ and X₂ are each a single bond, the general formula (I) and the general formula (II) may be respectively represented as follows:

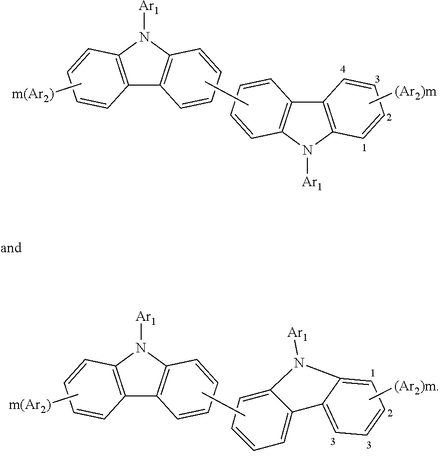

In a case where X₁ and X₂ are each arylene, in an example where X₁ is phenylene, and X₂ is divalent biphenylene, a structural formula of the general formula (I) may be as shown in any one of following formulas (I_1), (I_2), (I_3), (I_4) or (I_5).

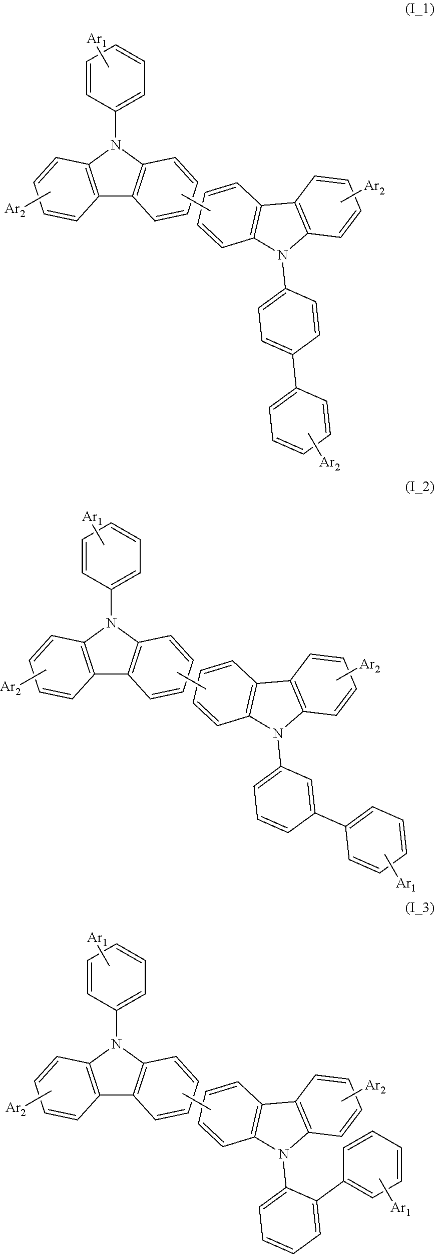

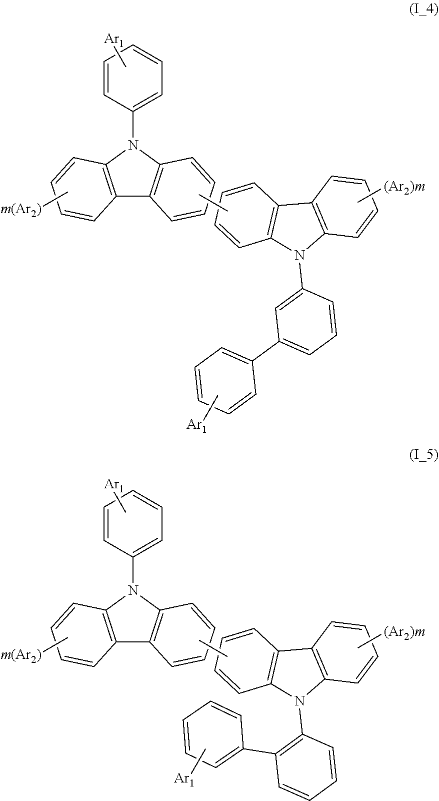

In the structural formulas(I_1), (I_2), (I_3), (I_4) and (I_5), Ar₁ bonded to divalent phenyl may be bonded to an ortho-position, a meta-position or a para-position of carbazole, and Ar₁ bonded to biphenylene may be bonded to an ortho-position, a meta-position or a para-position of one phenyl of the divalent biphenylene.

It will be noted that, according to a fact that m may be any one of 0, 1 and 2, it can be seen that, in a case where m is 0, the carbon atom 1, the carbon atom 2, the carbon atom 3 and the carbon atom 4 that are as shown in each of the general formula (I) and the general formula (II) are each bonded to one hydrogen atom; in a case where m is 1, one of the carbon atom 1, the carbon atom 2, the carbon atom 3 and the carbon atom 4 is bonded to Are; in a case where m is 2, any two of the carbon atom 1, the carbon atom 2, the carbon atom 3 and the carbon atom 4 are each bonded to Are.

An and Ar₂ may be each polycyclic aryl, and the polycyclic aryl may include xenyl or a structure as shown in a following formula (I_6)

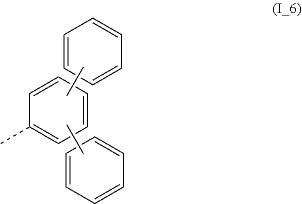

In a case where Ar₁ is the structure as shown in the formula (I_6), a dashed line in the formula (I_6) represents that Ar is bonded to a nitrogen (N) atom, and two phenyls of the structure may be respectively bonded to any two carbon atoms in an ortho-position, a meta-position or a para-position of the carbon atom to which the dashed line is connected. In a case where Ar₂ is the structure as shown in the formula (I_6), a dashed line in the formula (I_6) represents that Ar₂ is bonded to the carbon atom 1, the carbon atom 2, the carbon atom 3 or the carbon atom 4 of the carbazole, and two phenyls of the structure may be respectively bonded to any two carbon atoms in an ortho-position, a meta-position or a para-position of the carbon atom to which the dashed line is connected.

In a case where Ar₁ is xenyl such as biphenylene, one phenyl, located at an end, of the biphenylene may be bonded to a carbon atom, in an ortho-position, a meta-position or a para-position of a carbon atom bonded to the N atom of the carbazole. In a case where Ar₂ is xenyl such as biphenylene, the biphenylene may be bonded to the carbon atom 1, the carbon atom 2, the carbon atom 3 or the carbon atom 4 of the carbazole. In an example where the biphenylene is bonded to the carbon atom 1 of the carbazole, one phenyl of the biphenylene located at an end may be bonded to a carbon atom in an Ortho-position, a meta-position or a para-position of the carbon atom 1.

In some embodiments, the first host material GH_1 may be selected from any one of following structures.

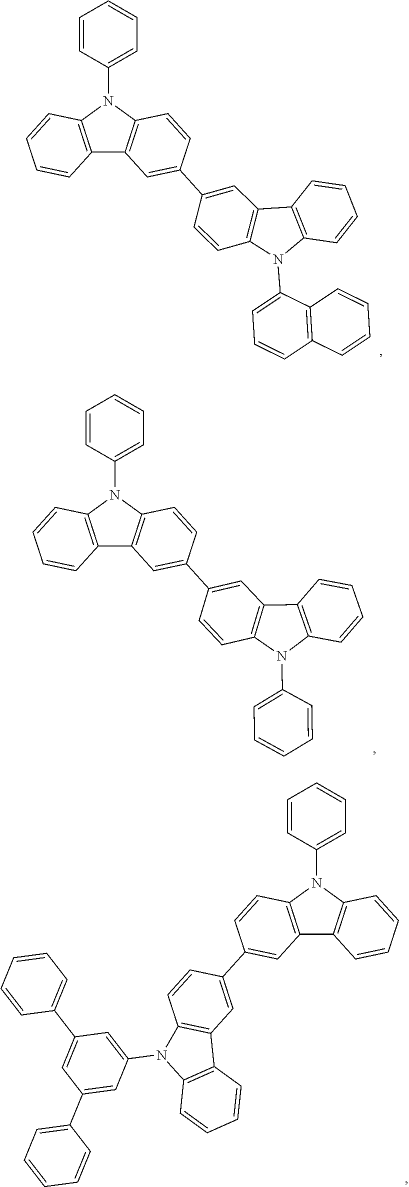

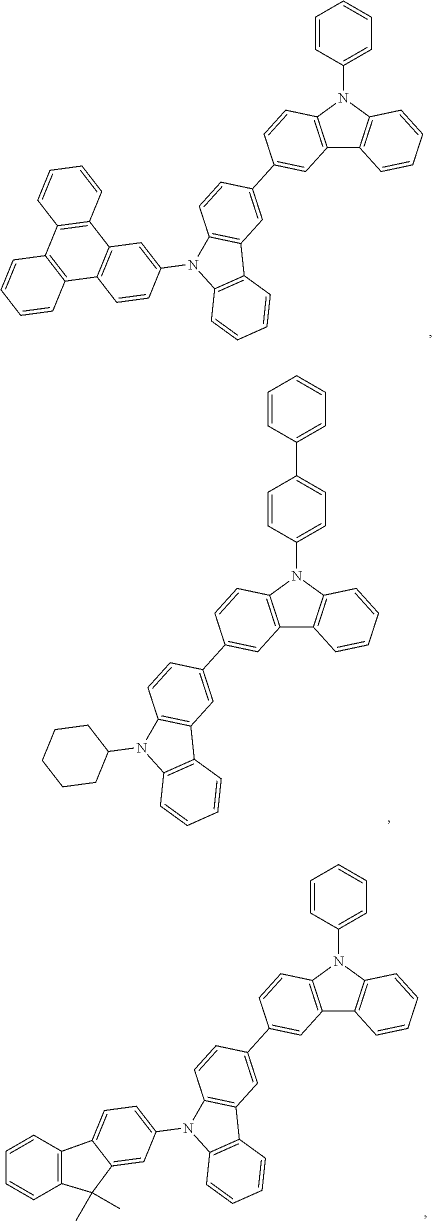 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-n3c4ccccc4c4cc(-c5ccc6c(c5)c5ccccc5n6C5CCCCC5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21]

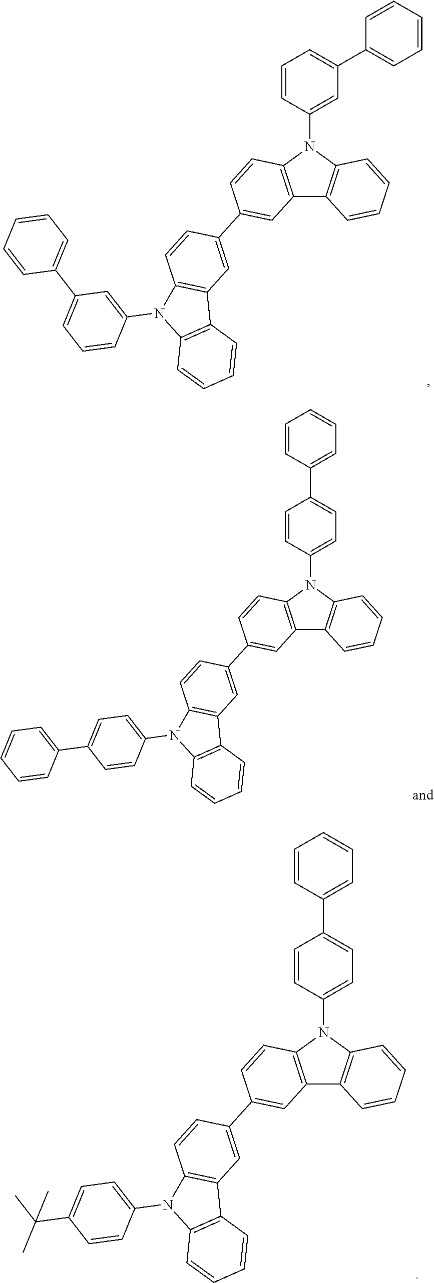 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; CC(C)(C)c1ccc(-n2c3ccccc3c3cc(-c4ccc5c(c4)c4ccccc4n5-c4ccc(-c5ccccc5)cc4)ccc32)cc1]

In some embodiments, the second host material GH_2 is selected from structures represented by a following general formula (III).

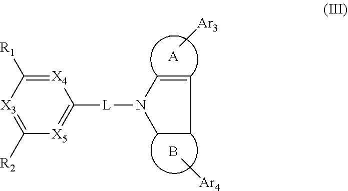

X₃, X₄ and X₅ are each independently selected from N or CR₃, and at least one of X₃ to X₅ is N; L is selected from any one of a single bond, substituted or unsubstituted alkyl in which a number of carbon atoms is in a range from 1 to 20, substituted or unsubstituted arylene in which a number of carbon atoms is in a range from 6 to 30, and substituted or unsubstituted heteroarylene, in which a number of carbon atoms in a range from 2 to 60, containing at least one of O, S, N, and Si.

A and B are each independently selected from any one of an aromatic ring in which a number of ring-forming carbon atoms is in a range from 6 to 30, and a heteroaromatic ring in which a number of ring-forming carbon atoms is in a range from 2 to 30.

Ar₃ and Ar₄ are each independently selected from any one of substituted or unsubstituted alkyl in which a number of carbon atoms is in a range from 2 to 20, substituted or unsubstituted aryl in which a number of ring-forming carbon atoms is in a range from 6 to 60, and substituted or unsubstituted heteroaryl in which a number of ring-forming carbon atoms is in a range from 6 to 60.

R₁, R₂ and R₃ are each independently selected from any one of hydrogen, substituted or unsubstituted alkyl in which a number of carbon atoms is in a range from 2 to 20, substituted or unsubstituted aryl in which a number of carbon atoms is in a range from 6 to 60, and substituted or unsubstituted heteroaryl, in which a number of carbon atoms is in a range from 6 to 60, containing at least one of O, S, N, and Si.

Substituents of L, Ar₃, Ar₄, R₁, R₂ and R₃ are each independently selected from any one or more of halogen, cyano, alkyl, aryl and heteroaryl.

The terms “aryl”, “arylene”, “heteroaryl” and “heteroarylene” mentioned in these embodiments each have a concept and a bonding manner that are the same as the terms “arylene”, “heteroaryl” and “heteroarylene” mentioned above, which is not specifically limited herein.

A and B are each independently selected from any one of the aromatic ring in which the number of ring-forming carbon atoms is in the range from 6 to 30 and the heteroarornatic ring in which the number of ring-forming carbon atoms is in the range from 2 to 30, which refers to that a group below may be fused heteroaryl, and a dashed line in the group represents that a nitrogen atom is bonded to L

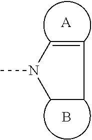

In a case where A and B are each a benzene ring, the group may be carbazole; in a case where A and B are each a naphthalene ring, the group may be represented by any one of following structures:

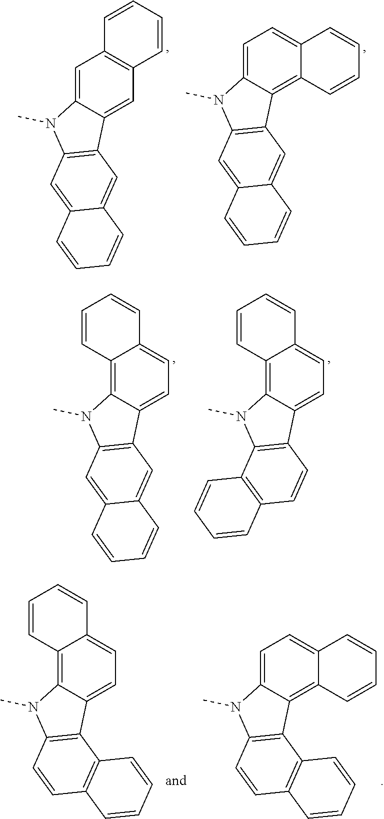

In some embodiments, the second host material GH_2 is selected from any one of following structures:

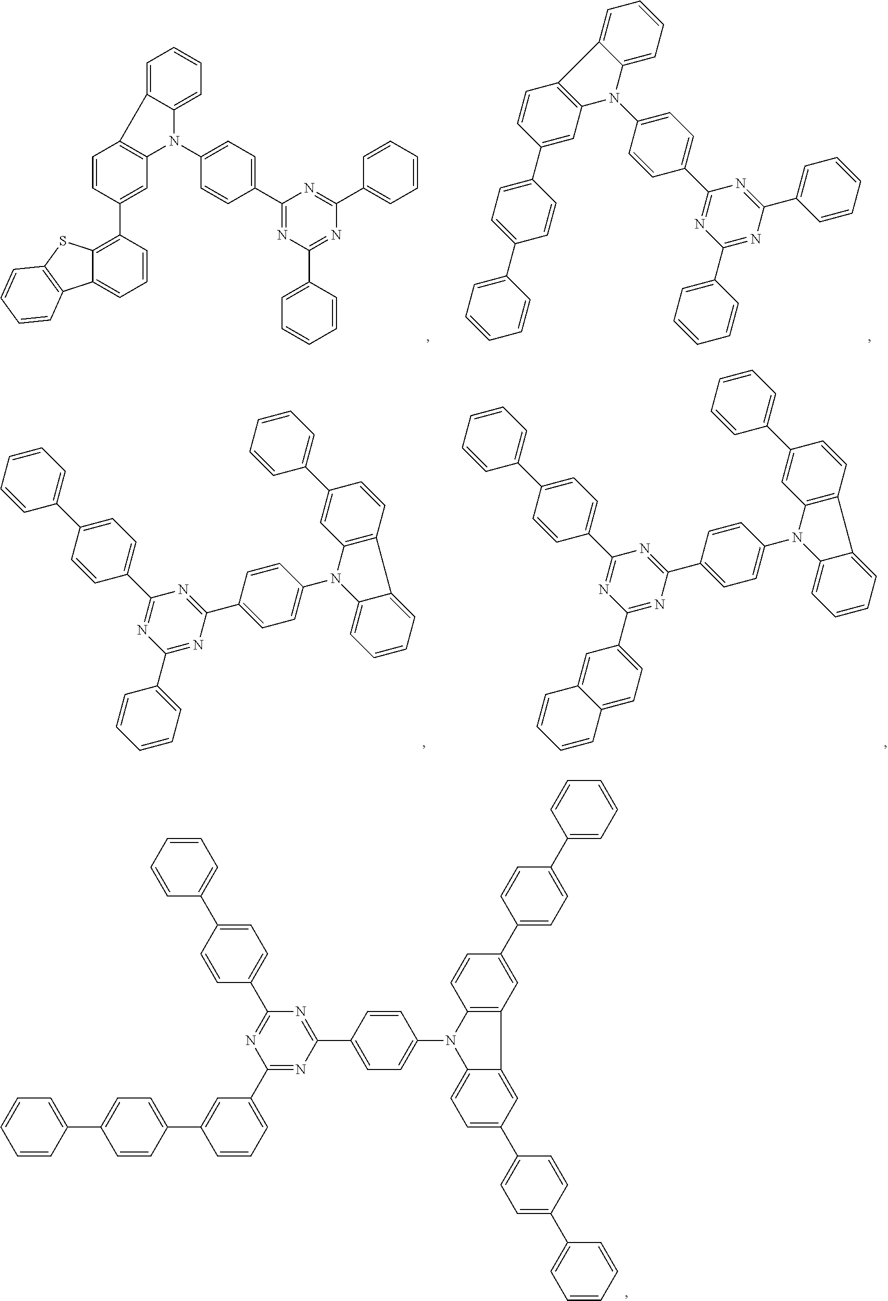

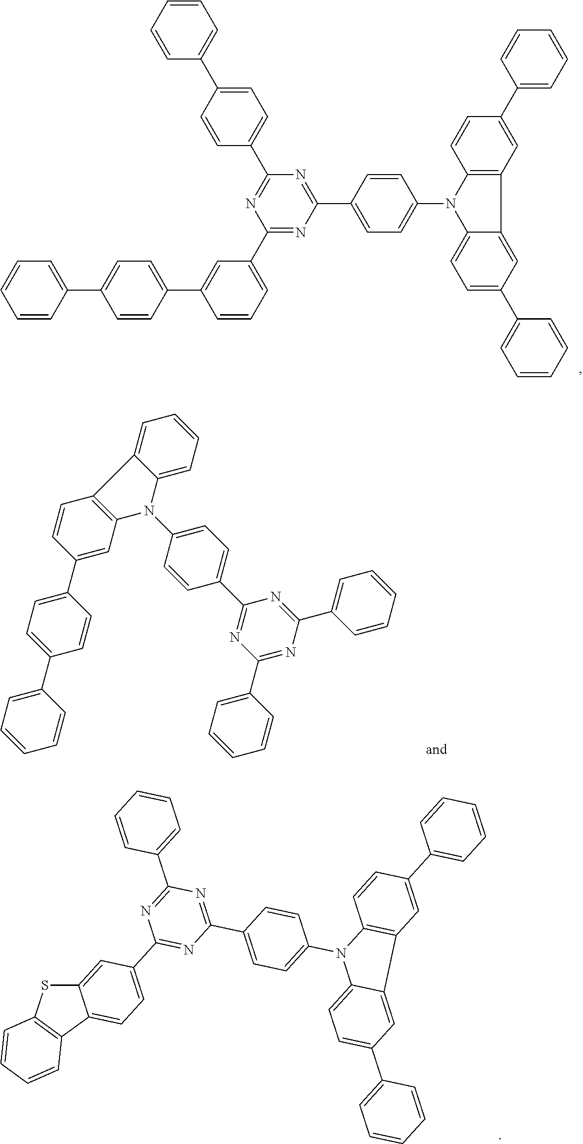 [SMILES: c1ccc(-c2ccc(-c3cccc(-c4nc(-c5ccc(-c6ccccc6)cc5)nc(-c5ccc(-n6c7ccc(-c8ccccc8)cc7c7cc(-c8ccccc8)ccc76)cc5)n4)c3)cc2)cc1 ; c1ccc(-c2ccc(-c3ccc4c5ccccc5n(-c5ccc(-c6nc(-c7ccccc7)nc(-c7ccccc7)n6)cc5)c4c3)cc2)cc1 ; c1ccc(-c2ccc3c(c2)c2cc(-c4ccccc4)ccc2n3-c2ccc(-c3nc(-c4ccccc4)nc(-c4ccc5c(c4)sc4ccccc45)n3)cc2)cc1]

In order to objectively describe technical effects of the embodiments provided in the present disclosure, the embodiments of the present disclosure will be exemplarily described in detail through comparative examples and experimental examples as follows.

It will be noted that in the comparative examples and the experimental examples as follows, the light-emitting devices 13 have a same structure including the anode, the hole injection layer (HIL) 136, the hole transporting layer (HTL) 134, the electron blocking layer (EBL) 138, the light-emitting layer 133, the hole blocking layer (HBL) 139, the electron transporting layer (ETL) 135, the electron injection layer (EIL) 137 and the cathode. Moreover, except the light-emitting layer 133, the same functional layers respectively in different light-emitting devices are each made of a same material.

Manufacturing methods of the light-emitting devices in the comparative examples and the experimental examples are the same, and may each include following steps.

In step 1, an ultrasonic treatment is performed, in a cleaning agent, on a glass plate on which an anode (ITO) is provided, and then the glass plate on which the anode is provided is rinsed in deionized water, degreased by performing an ultrasonic treatment thereon in a mixed solvent of acetone and ethanol, and baked in a clean environment until water is completely removed.

In step 2, the glass plate on which the anode is provided is placed in a vacuum cavity in which air is evacuated so that a pressure is in a range from 1×10⁻⁵ Pa to 1×10⁻⁶ Pa, and a vacuum evaporation, of which an evaporation rate is 0.1 nm/s and a thickness of an evaporated film is 100 nm, is performed on the anode to obtain a hole transporting layer.

In step 3, a vacuum evaporation is performed on the hole transporting layer to obtain a light-emitting layer of the device; the light-emitting layer includes a dual host material including a p-type material and an n-type material, and a structure represented by GD-1 is selected as the guest material; by means of a multi-components evaporation deposition manner, a ratio of a weight of the host material to a weight of the guest material is 90:10; an evaporation rate of the host material is 0.1 nm/s, a ratio of an evaporation rate of the guest material to the evaporation rate of the host material is 10:90, and a total thickness of an evaporated film is 30 nm.

In step 4, a vacuum evaporation, of which an evaporation rate is 0.1 nm/s and a thickness of an evaporated film is 30 nm, is performed on the light-emitting layer to obtain an electron transporting layer of the device.

In step 5, a vacuum evaporation is performed on the electron transporting layer to obtain a LiF layer, of which a thickness is 0.5 nm, serving as an electron injection layer.

In step 6, an Al layer, of which a thickness is 150 nm, is deposited to serve as a cathode of the device.

A structural formula HT-1 of the hole transporting layer, a structural formula GD-1 of the guest material and a structural formula ET-1 of the electron transporting layer are respectively as shown below.

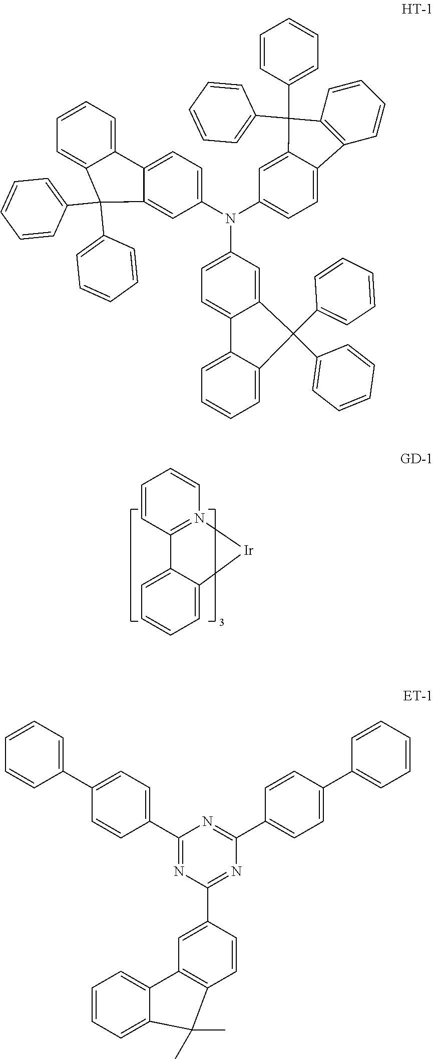

The p-type materials in the comparative examples and the experimental examples are respectively selected from following structures:

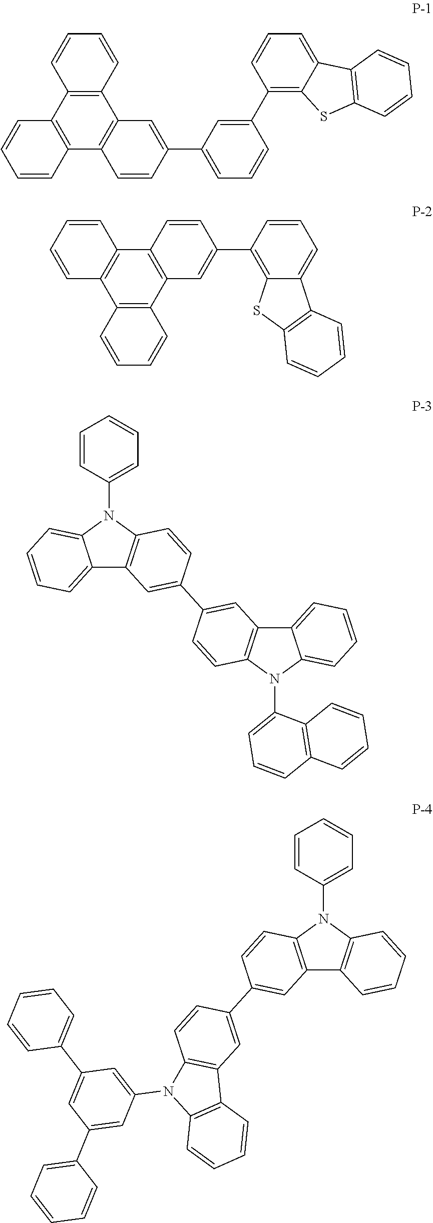

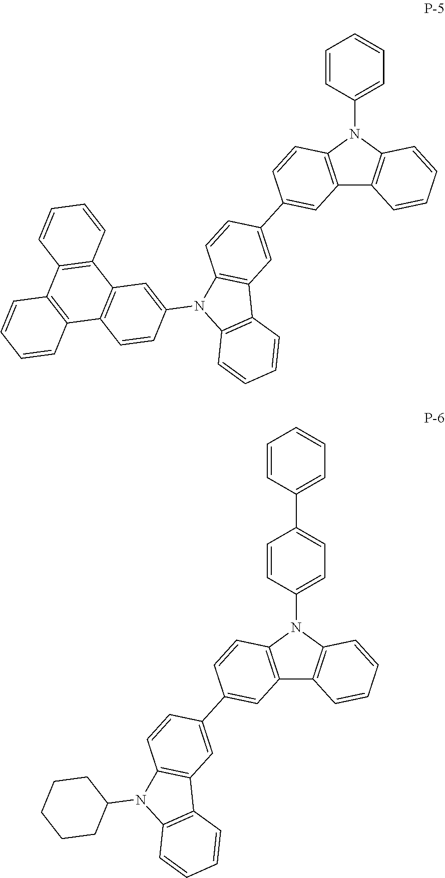 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-n3c4ccccc4c4cc(-c5ccc6c(c5)c5ccccc5n6C5CCCCC5)ccc43)cc2)cc1]

The n-type materials in the comparative examples and the experimental examples are respectively selected from following structures:

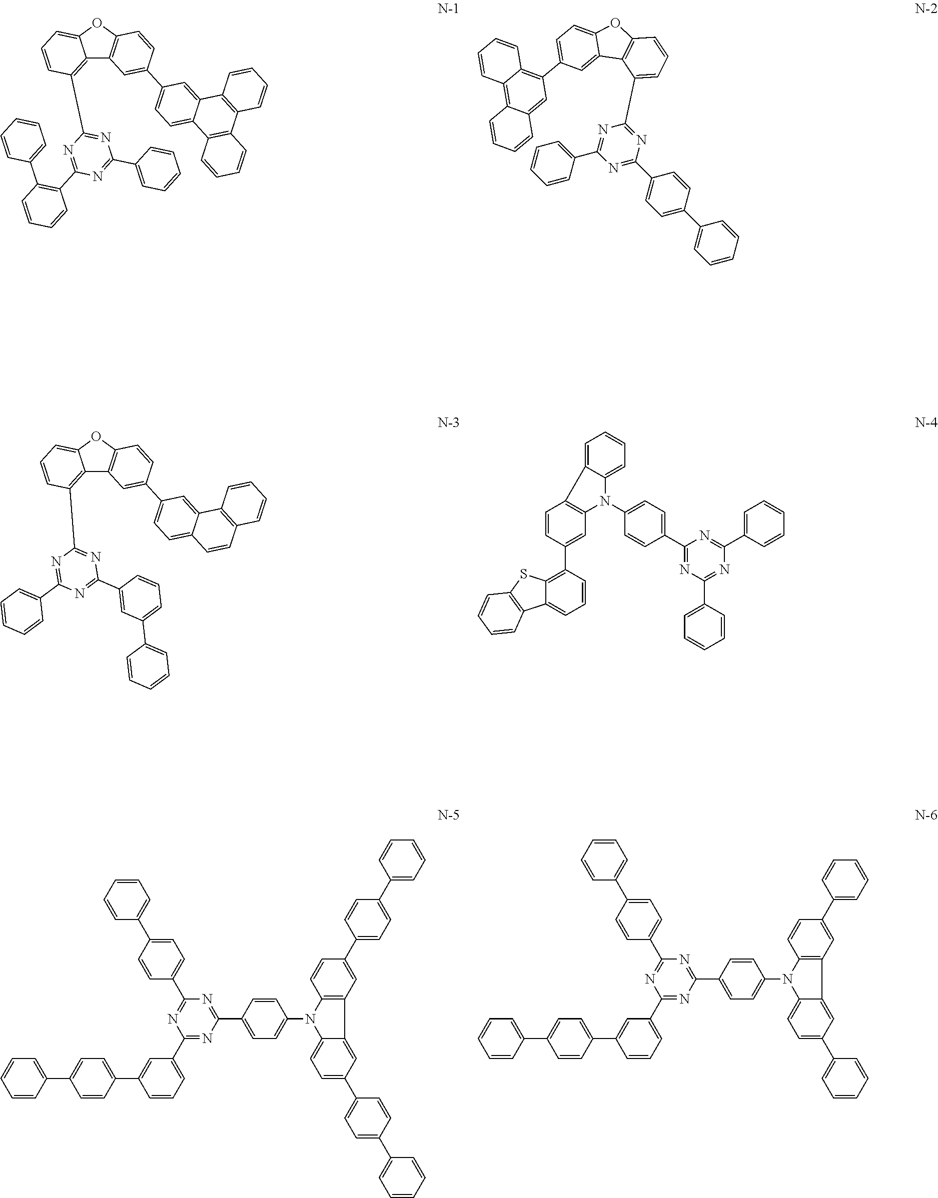

In the comparative examples, the p-type materials are respectively selected from structures represented by P-1 to P-3, and the n-type materials are respectively selected from structures represented by N-1 to N-3; in the experimental examples, the p-type materials are respectively selected from structures represented by P-4 to P-6, and the n-type materials are respectively selected from structures represented by N-4 to N-6.

In the comparative examples and the experimental examples, the difference between the LUMO energy level of the p-type material and the LUMO energy level of the n-type material, the hole mobility of the p-type material and the electron mobility of the s-type material are as shown in Table 1 below.

TABLE 1

| | | Hole mobility | Electron mobility |
|---|---|---|---|
| | LUMO_{p-type} − | (μh) of the | (μe) of the |
| Name | LUMO_{n-type} | p-type material | n-type material |
| Comparative | 0.24 | 2.5 × 10⁻⁹ cm²/Vs | 3.5 × 10⁻⁹ cm²/Vs |
| example 1 | | | |
| Comparative | 0.32 | 8.3 × 10⁻⁹ cm²/Vs | 9.6 × 10⁻⁹ cm²/Vs |
| example 2 | | | |
| Comparative | 0.28 | 2.6 × 10⁻⁸ cm²/Vs | 9.4 × 10⁻⁸ cm²/Vs |
| example 3 | | | |
| Experimental | 0.53 | 2.6 × 10⁻⁶ cm²/Vs | 2.6 × 10⁻⁷ cm²/Vs |
| example 1 | | | |
| Experimental | 0.54 | 4.5 × 10⁻⁶ cm²/Vs | 4.7 × 10⁻⁸ cm²/Vs |
| example 2 | | | |
| Experimental | 0.58 | 3.8 × 10⁻⁶ cm²/Vs | 5.6 × 10⁻⁸ cm²/Vs |
| example 3 | | | |

The performance tests are carried out on the light-emitting devices manufactured in the comparative examples and the experimental examples, and the test results are as shown in Table 2 below.

TABLE 2

| Device | Efficiency (cd/A) | Service life (i.e., LT95) (h) |
|---|---|---|
| Comparative | 44.6 | 60 |
| example 1 | | |
| Comparative | 45.5 | 59 |
| example 2 | | |
| Comparative | 43.3 | 55 |
| example 3 | | |
| Experimental | 50.6 | 65 |
| example 1 | | |
| Experimental | 51.7 | 70 |
| example 2 | | |
| Experimental | 50.4 | 72 |
| example 3 | | |

With reference to Table 1 and Table 2, it can be seen that the difference between the LUMO energy level of the first host material and the LUMO energy level of the second host material is greater than or equal to 0.5 eV, so that in the process of transporting the electrons and the holes, the relatively large potential barrier (i.e., the electron trap) may be created between the LUMO energy level of the second host material and the LUMO energy level of the first host material. Compared with the related art in which the difference in between the LUMO energy level of the first host material and the LUMO energy level of the second host material is less than 0.5 eV, the electron mobility of the entire light-emitting device in the embodiments of the present disclosure may be reduced, which makes the transport of the electrons and the holes tend to be balanced to adjust the recombination region of the electrons and the holes, so as to make the recombination region of the electrons and the holes move towards the side of the light-emitting layer away from the electron blocking layer. In this way, the problem, caused by the fact that the exciton concentration at the side of the light-emitting layer proximate to the electron blocking layer is too high due to the increase of the temperature, that the device stability and the device efficiency are reduced may be counteracted or ameliorated. Furthermore, in the case where the difference between the LUMO energy level of the first host material and the LUMO energy level of the second host material is determined (e.g., greater than or equal to 0.5 eV), the first host material having the relatively high hole mobility and the second host material having the relatively low electron mobility are provided, so as to further improve the hole mobility of the entire light-emitting device 13 and reduce the electron mobility of the entire light-emitting device 13. As a result, it is possible to further adjust the recombination region of the electrons and the holes, which makes the recombination region of the electrons and the holes move towards the side of the light-emitting layer away from the electron blocking layer, so that the problem, caused by the fact that the exciton concentration at the side of the light-emitting layer proximate to the electron blocking layer is too high due to the increase of the temperature, that the device stability and the device efficiency are reduced may be further counteracted or ameliorated.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device that emits green light, comprising:
a first electrode and a second electrode that are arranged in sequence; and
a light-emitting layer disposed between the first electrode and the second electrode; wherein
the light-emitting layer including a first host material and a second host material, and the first host material and the second host material form an exciplex; and
a difference between a lowest unoccupied molecular orbital (LUMO) energy level of the first host material and a LUMO energy level of the second host material is greater than or equal to 0.5 eV; under a same test condition, a difference between an order of magnitude of a hole mobility of the first host material and an order of magnitude of an electron mobility of the second host material is greater than or equal to 1.

2. The light-emitting device that emits the green light according to claim 1, wherein
under a test condition where an electric field intensity is 5000 V^{1/2}/m^{1/2}, the hole mobility of the first host material is in a range from 1×10⁻⁸ cm²V⁻¹s⁻¹ to 1×10⁻⁸ cm²V⁻¹s⁻¹, inclusive, and the electron mobility of the second host material is in a range from 1×10⁻⁹ cm²V⁻¹s⁻¹ to 1×10⁻⁸ cm²V⁻¹s⁻¹, inclusive.

3. The light-emitting device that emits the green light according to claim 1, wherein
the LUMO energy level of the first host material is in a range from −2.4 eV to −2.0 eV, inclusive; and
the LUMO energy level of the second host material is in a range from −3.0 eV to −2.7 eV, inclusive.

4. The light-emitting device that emits the green light according to claim 1, wherein
a full width at half maximum of an emission spectrum of the exciplex is greater than or equal to 90 nm.

5. The light-emitting device that emits the green light according to claim 4, wherein
the full width at half maximum of the emission spectrum of the exciplex is in a range from 100 nm to 110 nm, inclusive.

6. The light-emitting device that emits the green light according to claim 1, wherein
the first host material is selected from structures each having two carbazoles.

7. The light-emitting device that emits the green light according to claim 6, wherein
the first host material is selected from structures represented by following general formula (I) and general formula (II): 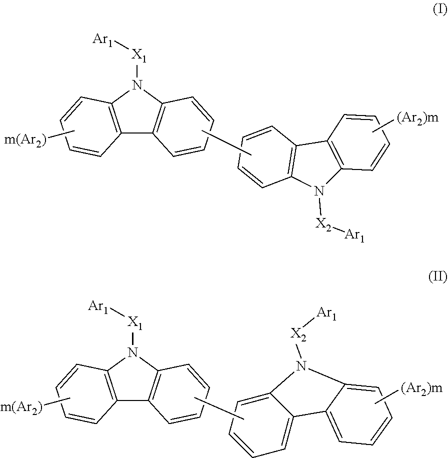
wherein X₁ and X₂ are the same or different, and are each independently selected from any one of a single bond, substituted or unsubstituted arylene in which a number of ring-forming carbon atoms is in a range from 6 to 30, and substituted or unsubstituted heteroarylene in which a number of ring-forming carbon atoms is in a range from 2 to 30;
each Ar₁ is the same or different, and is independently selected from any one of hydrogen, deuterium, halogen, cyano, nitro, amino, substituted or unsubstituted alkyl in which a number of carbon atoms is in a range from 1 to 20, substituted or unsubstituted cycloalkyl in which a number of carbon atoms is in a range from 3 to 60, substituted or unsubstituted aryl in which a number of ring-forming carbon atoms is in a range from 6 to 60, and substituted or unsubstituted heteroaryl, in which a number of ring-forming carbon atoms is in a range from 2 to 60, containing at least one of O, S, N, and Si;
each Ar₂ is the same or different, and is independently selected from any one of fluorine, cyano, substituted or unsubstituted alkyl in which a number of carbon atoms is in a range from 1 to 20, substituted or unsubstituted alkoxy in which a number of carbon atoms is in a range from 1 to 20, substituted or unsubstituted aryl in which a number of ring-forming carbon atoms is in a range from 6 to 30, and substituted or unsubstituted heteroaryl in which a number of ring-forming carbon atoms is in a range from 2 to 30;
a substituent of X₁ or X₂ is selected from any one of alkyl in which a number of carbon atoms is in a range from 1 to 10, cycloalkyl in which a number of ring-forming carbon atoms is in a range from 3 to 20, aryl in which a number of ring-forming carbon atoms is in a range from 6 to 30, and heteroaryl, in which a number of ring-forming carbon atoms is in a range from 2 to 30, containing at least one of O, S, N, and Si,
a substituent of Ar₁ is selected from any one of alkyl in which a number of carbon atoms is in a range from 4 to 6, cycloalkyl in which a number of ring-forming carbon atoms is in a range from 3 to 10, aryl in which a number of ring-forming carbon atoms is in a range from 6 to 30, and heteroaryl, in which a number of ring-forming carbon atoms is in a range from 2 to 30, containing at least one of O, S, N, and Si:
a substituent of Ar₂ is selected from any one of alkyl in which a number of carbon atoms is in a range from 4 to 20, cycloalkyl in which a number of ring-forming carbon atoms is in a range from 3 to 10, aryl in which a number of ring-forming carbon atoms is in a range from 6 to 30, and heteroaryl, in which a number of ring-forming carbon atoms is in a range from 2 to 30, containing at least one of O, S, N, and Si;
m is selected from any one of 0, 1 and 2.

8. The light-emitting device that emits the green light according to claim 7, wherein
the first host material is selected from any one of following structures:

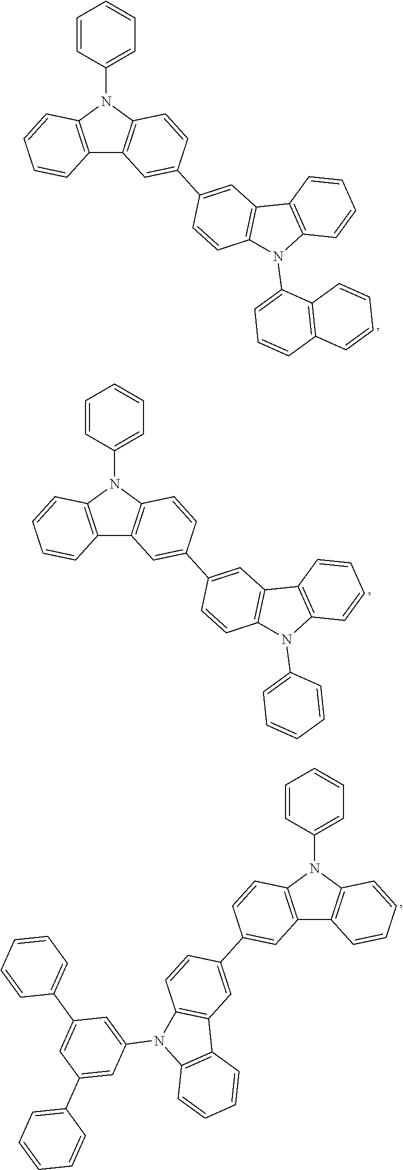

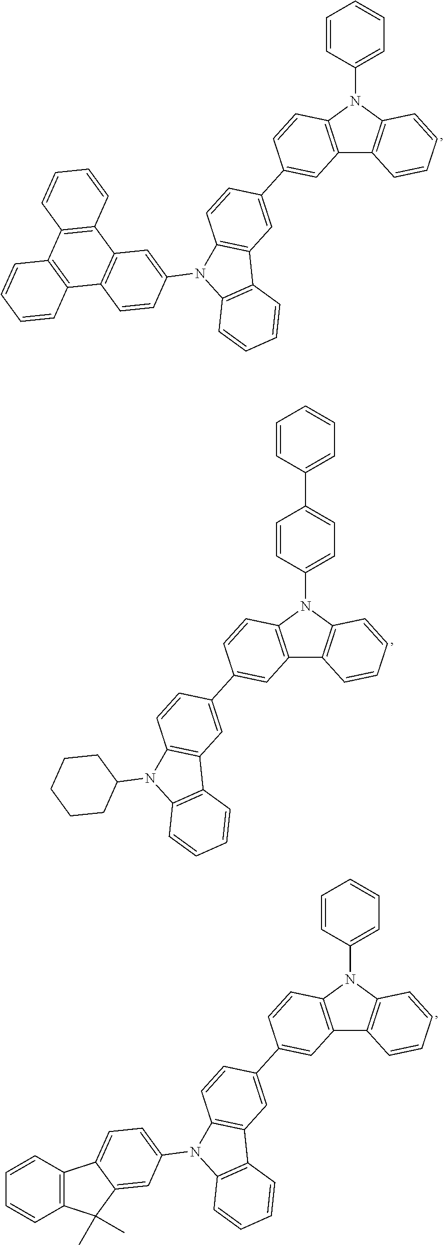 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-n3c4ccccc4c4cc(-c5ccc6c(c5)c5ccccc5n6C5CCCCC5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21]

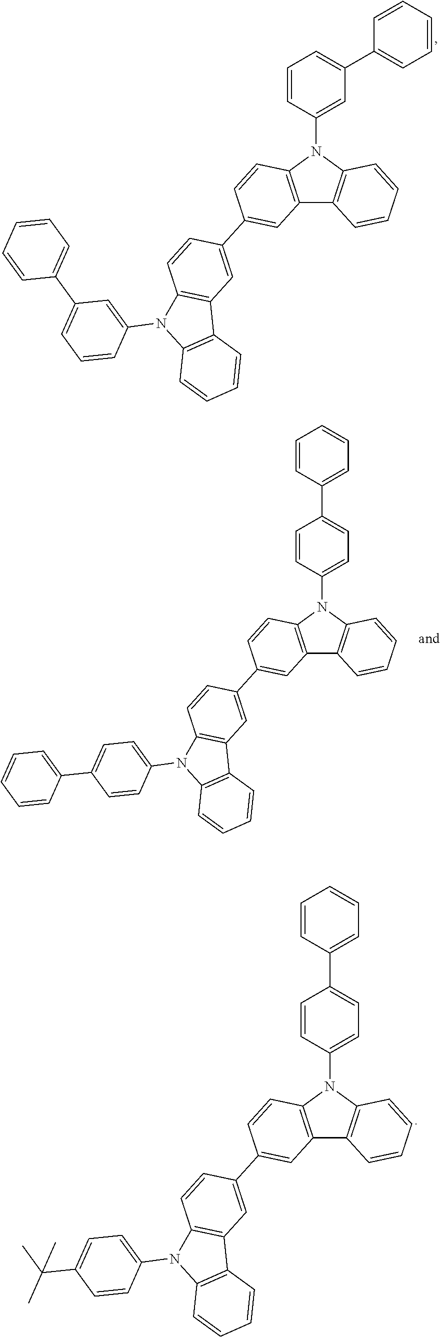 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; CC(C)(C)c1ccc(-n2c3ccccc3c3cc(-c4ccc5c(c4)c4ccccc4n5-c4ccc(-c5ccccc5)cc4)ccc32)cc1]

9. The light-emitting device that emits the green light according to claim 1, wherein
the second host material is selected from structures represented by a following general formula (III): 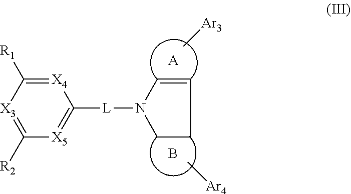
wherein X₃, X₄ and X₅ are each independently selected from N or CR₃, and at least one of X₃ to X₅ is N; L is selected from any one of a single bond, substituted or unsubstituted alkyl in which a number of carbon atoms is in a range from 1 to 20, substituted or unsubstituted arylene in which a number of carbon atoms is in a range from 6 to 30, and substituted or unsubstituted heteroarylene, in which a number of carbon atoms is in a range from 2 to 60, containing at least one of O, S, N, and Si;
A and B are each independently selected from any one of an aromatic ring in which a number of ring-forming carbon atoms is in a range from 6 to 30, and a heteroaromatic ring in which a number of ring-forming carbon atoms is in a range from 2 to 30;
Ar₃ and Ar₄ are each independently selected from any one of substituted or unsubstituted alkyl in which a number of carbon atoms is in a range from 2 to 20, substituted or unsubstituted aryl in which a number of ring-forming carbon atoms is in a range from 6 to 60, and substituted or unsubstituted heteroaryl in which a number of ring-forming carbon atoms is in a range from 6 to 60;
R₁, R₂ and R₃ are each independently selected from any one of hydrogen, substituted or unsubstituted alkyl in which a number of carbon atoms is in a range from 2 to 20, substituted or unsubstituted aryl in which a number of carbon atoms is in a range from 6 to 60, and substituted or unsubstituted heteroaryl, in which a number of carbon atoms is in a range from 6 to 60, containing at least one of O, S, N, and Si;
substituents of L, Ar₃, Ar₄, R₁, R₂ and R₃ are each independently selected from any one or more of halogen, cyano, alkyl, aryl and heteroaryl.

10. The light-emitting device that emits the green light according to claim 9, wherein
the second host material is selected from any one of following structures:

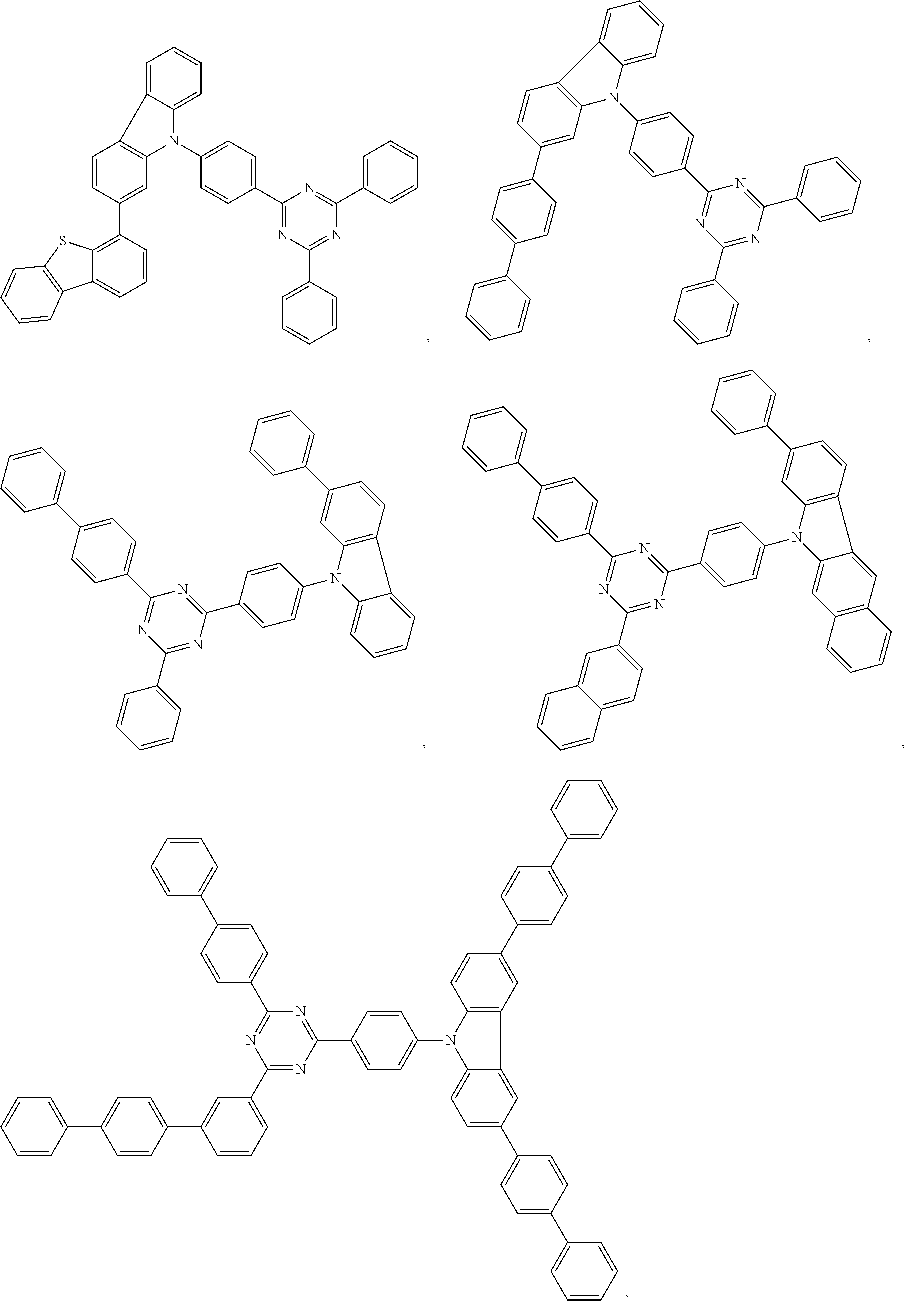

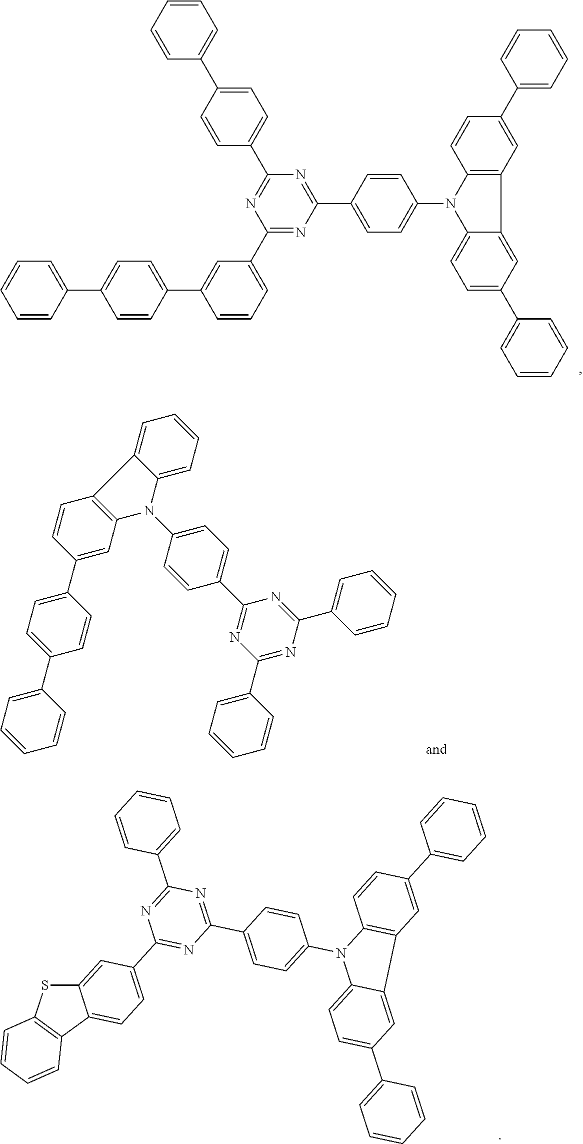 [SMILES: c1ccc(-c2ccc(-c3cccc(-c4nc(-c5ccc(-c6ccccc6)cc5)nc(-c5ccc(-n6c7ccc(-c8ccccc8)cc7c7cc(-c8ccccc8)ccc76)cc5)n4)c3)cc2)cc1 ; c1ccc(-c2ccc(-c3ccc4c5ccccc5n(-c5ccc(-c6nc(-c7ccccc7)nc(-c7ccccc7)n6)cc5)c4c3)cc2)cc1 ; c1ccc(-c2ccc3c(c2)c2cc(-c4ccccc4)ccc2n3-c2ccc(-c3nc(-c4ccccc4)nc(-c4ccc5c(c4)sc4ccccc45)n3)cc2)cc1]

11. The light-emitting device that emits the green light according to claim 1, further comprising a hole transporting layer disposed between the first electrode and the light-emitting layer and an electron transporting layer disposed between the second electrode and the light-emitting layer;
wherein a material of the hole transporting layer is selected from any one or more of a carbazole compound, hexaazatriphenylenehexacabonitrile, 2,3,5,6-Tetrafluoro-7,7′,8,8′-tetracyanoquinodimethane and 1,2,3-tris[(cyano)(4-cyano-2,3,5,6-tetrafluorophenyl)methylene)cyclopropane; and
a material of the electron transporting layer is selected from compounds containing any one or more groups of triazine, pyridine, azine and benzimidazole.

12. The light-emitting device that emits the green light according to claim 1, wherein
the light-emitting layer further includes a guest material, and the guest material is selected from one or more of following structures:

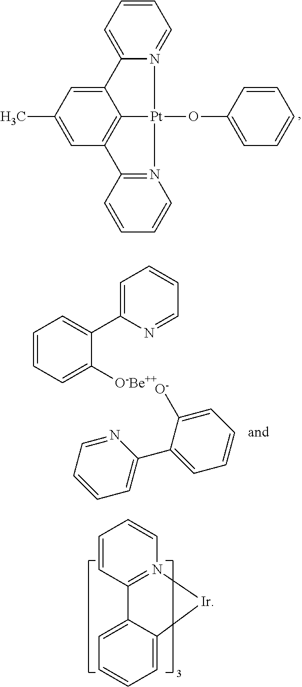

13. A light-emitting substrate, comprising:
a substrate; and
a plurality of light-emitting devices disposed on the substrate;
wherein at least one light-emitting device is the light-emitting device that emits the green light according to claim 1.

14. A light-emitting apparatus, comprising the light-emitting substrate according to claim 13.

15. The light-emitting device that emits the green light according to claim 1, wherein
the first electrode is an anode, and a material of the anode is selected from high work function materials.

16. The light-emitting device that emits the green light according to claim 1, wherein
the second electrode is a cathode, and a material of the cathode is selected from low work function materials.

17. The light-emitting substrate according to claim 13, wherein
under a test condition where an electric field intensity is 5000 V^{1/2}/m^{1/2}, the hole mobility of the first host material is in a range from 1×10⁻⁸ cm²V⁻¹s⁻¹ to 1×10⁻⁶ cm²V⁻¹s⁻¹ inclusive, and the electron mobility of the second host material is in a range from 1×10⁻⁹ cm²V⁻¹s⁻¹ to 1×10⁻⁶ cm²V⁻¹s⁻¹ inclusive.

18. The light-emitting substrate according to claim 13, wherein
the LUMO energy level of the first host material is in a range from −2.4 eV to −2.0 eV, inclusive; and
the LUMO energy level of the second host material is in a range from −3.0 eV to −2.7 eV, inclusive.

19. The light-emitting substrate according to claim 13, wherein
a full width at half maximum of an emission spectrum of the exciplex is greater than or equal to 90 nm.

20. The light-emitting substrate according to claim 13, wherein
the first host material is selected from structures each having two carbazoles.
